(19) United States
(12) Patent Application Publication
(10) Pub. No.: US 2025/0370262 A1
(43) Pub. Date: Dec. 4, 2025

(54) DISPLAY DEVICE AND OPTICAL DEVICE

(71) Applicant: Samsung Display Co., LTD., Yongin-si (KR)

(72) Inventor: Sang Ho KIM, Yongin-si (KR)

(21) Appl. No.: 19/079,357

(22) Filed: Mar. 13, 2025

(30) Foreign Application Priority Data
Jun. 4, 2024 (KR) 10-2024-0073161

(51) Int. Cl. G02B 27/01; G02B 5/30; G02B 27/28; G09G 3/3233

(52) U.S. Cl. CPC G02B 27/0172; G02B 5/3025; G02B 27/28; G02B 2027/0178; G09G 3/3233; G09G 2300/0426; G09G 2300/0819; G09G 2300/0852

(57) ABSTRACT

The present disclosure relates to a display device, and more particularly, to a display device and an optical device whose image quality may be improved. The display device includes: a display panel; and a first optical layer on the display panel, wherein the first optical layer includes a geometric phase module having a cross section with a curved shape.

### CROSS-REFERENCE TO RELATED APPLICATION

The present application claims priority to and the benefit of Korean Patent Application No. 10-2024-0073161, filed on Jun. 4, 2024, in the Korean Intellectual Property Office, the entire disclosure of which is incorporated by reference herein.

### BACKGROUND

### 1. Field

The present disclosure relates to a display device, and more particularly, to a display device and an optical device whose image quality may be improved.

### 2. Description of the Related Art

A head mounted display (HMD) is an image display device that is worn on a user's head in the form of glasses or a helmet and forms a focus at a distance close to user's eyes in front of the user's eyes. The head mounted display may implement virtual reality (VR) and/or augmented reality (AR).

The head mounted display magnifies and displays an image displayed by a small display device using a plurality of lenses. Therefore, a display device applied to the head mounted display needs to provide a high-resolution image, for example, an image having a resolution of 3000 pixels per inch (PPI) or more. To this end, an organic light emitting diode on silicon (OLEDoS), which is a small organic light emitting display device having a high resolution, has been used as the display device applied to the head mounted display. The OLEDOS is a device that displays an image by disposing organic light emitting diodes (OLEDs) on a semiconductor wafer substrate on which complementary metal oxide semiconductors (CMOSs) are disposed.

### SUMMARY

Aspects and features of embodiments of the present disclosure provide a display device and an optical device whose image quality may be improved.

According to one or more embodiments of the present disclosure, there is provided a display device including: a display panel; and a first optical layer on the display panel, and wherein the first optical layer includes a geometric phase module having a cross section with a curved shape.

The first optical layer may further include a lens between the display panel and the geometric phase module.

The geometric phase module may include a geometric phase lens, and a curvature of the geometric phase lens and a curvature of the lens may be the same as each other.

The first optical layer may further include: an absorptive polarization layer on the display panel; a translucent mirror on the absorptive polarization layer; a first lens on the translucent mirror; a second lens on the first lens; a phase delay layer on the second lens; a reflective polarization layer on the phase delay layer; and a third lens on the reflective polarization layer.

The geometric phase module may be between the absorptive polarization layer and the translucent mirror.

The first optical layer may further include: an absorptive polarization layer on the display panel; a first phase delay layer on the absorptive polarization layer; a translucent mirror on the first phase delay layer; a first lens on the translucent mirror; a second lens on the first lens; a second phase delay layer on the second lens; a reflective polarization layer on the second phase delay layer; and a third lens on the reflective polarization layer.

The geometric phase module may be on the third lens.

The geometric phase module may include: a first linear polarization conversion layer; a first phase delay layer on the first linear polarization conversion layer; and a geometric phase lens on the first phase delay layer, and the geometric phase lens may have a cross section with a curved shape.

The geometric phase module may further include: a second phase delay layer on the geometric phase lens; a second linear polarization conversion layer on the second phase delay layer; and a third phase delay layer on the second linear polarization conversion layer.

The display device may further include a second optical layer between the display panel and the first optical layer.

The second optical layer may include a plurality of micro lenses.

The plurality of micro lenses may correspond to a plurality of color filters of the display panel.

The display device may further include a filling layer between the first optical layer and the second optical layer.

According to another aspect of the present disclosure, there is provided an optical device including: a display device; and an optical path conversion member on the display device, wherein the display device includes: a display panel; and a first optical layer on the display panel, and the first optical layer includes a geometric phase module having a cross section with a curved shape.

In one or more embodiments, an electronic device comprising a display device, the display device includes: a display panel; a first optical layer on the display panel; and a second optical layer between the display panel and the first optical layer, wherein the first optical layer comprises a geometric phase module having a cross section with a curved shape.

The electronic device includes a mobile phone, a smartphone, a tablet personal computer, a mobile communication terminal, an electronic book, a portable multimedia player (PMP), a navigation system, an ultra mobile PC (UMPC), a television, a laptop, a monitor, a billboard, or an Internet-of-Things (IoT) terminal.

With a display device and an optical device according to the present disclosure, image quality of the display device and the optical device may be improved.

The effects of the present disclosure are not limited to the above-described effects and other effects which are not described herein will become apparent to those skilled in the art from the following description.

### BRIEF DESCRIPTION OF THE DRAWINGS

The above and other aspects and features of the present disclosure will become more apparent by describing in detail example embodiments thereof with reference to the attached drawings, in which:

FIG. 1 is an exploded perspective view illustrating a display device according to one or more embodiments;

FIG. 2 is a block diagram illustrating the display device according to one or more embodiments;

FIG. 3 is an equivalent circuit diagram of a first pixel according to one or more embodiments;

FIG. 4 is a layout diagram illustrating an example of a display panel according to one or more embodiments;

FIGS. 5 and 6 are layout diagrams illustrating one or more embodiments of a display area of FIG. 4;

FIG. 7 is a cross-sectional view illustrating an example of the display panel taken along the line I1-I1′ of FIG. 5;

FIG. 8 is a detailed configuration diagram of an optical layer of FIG. 7;

FIG. 9 is a detailed configuration diagram of a geometric phase module of FIG. 8;

FIGS. 10 and 11 are views for describing a movement path of light in the display device of FIG. 8;

FIG. 12 is a detailed configuration diagram of another example embodiment of the optical layer of FIG. 7;

FIG. 13 is a detailed configuration diagram of a geometric phase module of FIG. 12;

FIGS. 14 and 15 are views for describing a movement path of light in a display device of FIG. 12;

FIG. 16 is a detailed configuration diagram of another embodiment of the geometric phase module of FIG. 12;

FIG. 17 is a cross-sectional view illustrating another example embodiment of the display device taken along the line I1-I1′ of FIG. 5;

FIG. 18 is a cross-sectional view of a linear polarization conversion layer according to one or more embodiments;

FIG. 19 is a perspective view illustrating a head mounted display device according to one or more embodiments;

FIG. 20 is an exploded perspective view illustrating an example of the head mounted display device of FIG. 19; and

FIG. 21 is a perspective view illustrating a head mounted display according to one or more embodiments.

### DETAILED DESCRIPTION

The present disclosure will now be described more fully hereinafter with reference to the accompanying drawings, in which embodiments of the present disclosure are shown. The present disclosure may, however, be embodied in different forms and should not be construed as limited to the embodiments set forth herein. Rather, these embodiments are provided so that the present disclosure will be thorough and complete, and will fully convey the scope of the present disclosure to those skilled in the art.

It will also be understood that when a layer is referred to as being “on” another layer or substrate, it can be directly on the other layer or substrate, or intervening layers may also be present. The same reference numbers indicate the same components throughout the specification. In the attached figures, the thickness of layers and regions is exaggerated for clarity.

Although the terms “first”, “second”, etc. may be used herein to describe various elements, these elements, should not be limited by these terms. These terms may be used to distinguish one element from another element. Thus, a first element discussed below may be termed a second element without departing from teachings of one or more embodiments. The description of an element as a “first” element may not require or imply the presence of a second element or other elements. The terms “first”, “second”, etc. may also be used herein to differentiate different categories or sets of elements. For conciseness, the terms “first”, “second”, etc. may represent “first-category (or first-set)”, “second-category (or second-set)”, etc., respectively.

Features of various embodiments of the present disclosure may be combined partially or totally. As will be clearly appreciated by those skilled in the art, technically various interactions and operations are possible. Various embodiments can be practiced individually or in combination.

For the purposes of the present disclosure, expressions, such as “at least one of,” “one of,” and “selected from,” when preceding a list of elements, modify the entire list of elements and do not modify the individual elements of the list. For example, “at least one of X, Y, and Z,” “at least one of X, Y, or Z,” and “at least one selected from the group consisting of X, Y, and Z” may be construed as X only, Y only, Z only, any combination of two or more of X, Y, and Z, such as, for instance, XYZ, XYY, XZ, YZ, and ZZ, or any variation thereof. Similarly, the expression, such as “at least one of A and/or B” may include A, B, or A and B. As used herein, the term “and/or” includes any and all combinations of one or more of the associated listed items. For example, the expression, such as “A and/or B” may include A, B, or A and B. Further, the use of “may” when describing embodiments of the present disclosure refers to “one or more embodiments of the present disclosure”.

As used herein, the term “substantially,” “about,” “approximately,” and similar terms are used as terms of approximation and not as terms of degree, and are intended to account for the inherent deviations in measured or calculated values that would be recognized by those of ordinary skill in the art. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value. Further, the use of “may” when describing embodiments of the present disclosure refers to “one or more embodiments of the present disclosure.”

Also, any numerical range disclosed and/or recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, for example, having a minimum value equal to or greater than 1.0 and a maximum value equal to or less than 10.0, such as, for example, 2.4 to 7.6. Any maximum numerical limitation recited herein is intended to include all lower numerical limitations subsumed therein, and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein. All such ranges are intended to be inherently described in this specification such that amending to expressly recite any such subranges would comply with the requirements of 35 U.S.C. § 112(a) and 35 U.S.C. § 132(a).

Also, any numerical range disclosed and/or recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, for example, having a minimum value equal to or greater than 1.0 and a maximum value equal to or less than 10.0, such as, for example, 2.4 to 7.6. Any maximum numerical limitation recited herein is intended to include all lower numerical limitations subsumed therein, and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein. All such ranges are intended to be inherently described in this specification such that amending to expressly recite any such subranges would comply with the requirements of 35 U.S.C. § 112(a) and 35 U.S.C. § 132(a).

A person of ordinary skill in the art would appreciate, in view of the present disclosure in its entirety, that each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner unless otherwise stated or implied.

Hereinafter, embodiments will be described in detail with reference to the accompanying drawings.

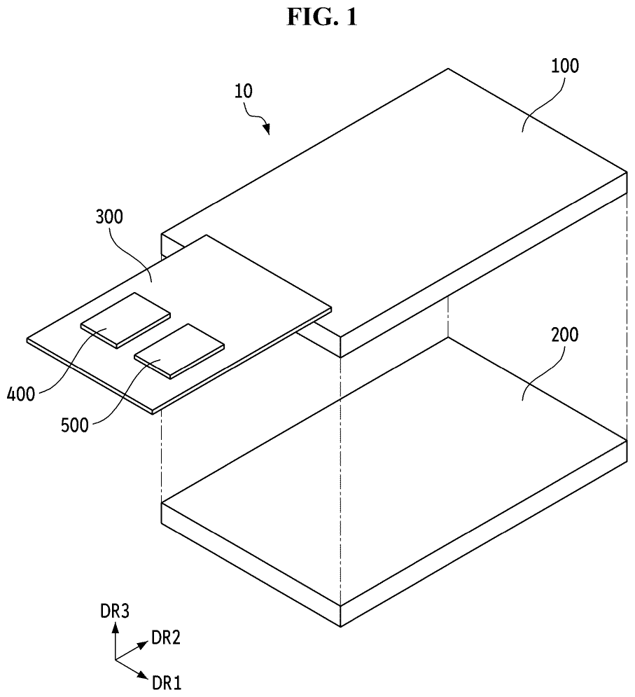

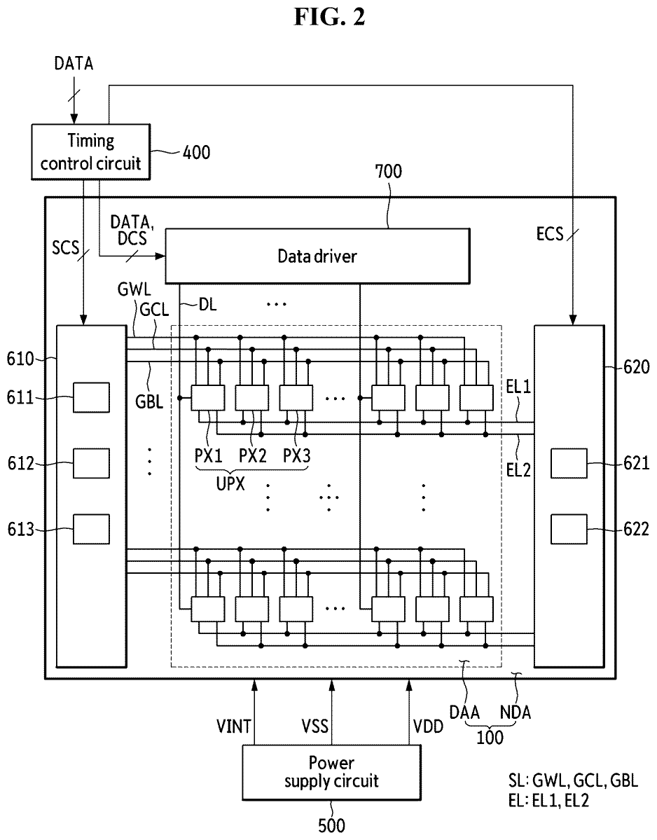

FIG. 1 is an exploded perspective view illustrating the display device according to one or more embodiments. FIG. 2 is a block diagram illustrating the display device according to one or more embodiments.

Referring to FIGS. 1 and 2, a display device 10 according to one or more embodiments is a device that displays a moving image and/or a still image. The display device 10 according to one or more embodiments may be applied to portable electronic devices such as mobile phones, smartphones, tablet personal computers (PCs), mobile communication terminals, electronic notebooks, electronic books, portable multimedia players (PMPs), navigation devices, and/or ultra mobile PCs (UMPCs). For example, the display device 10 according one or more embodiments may be applied as a display unit of televisions, laptop computers, monitors, billboards, and/or the Internet of Things (IOTs). Alternatively, the display device 10 according one or more embodiments may be applied to smart watches, watch phones, and/or head mounted displays (HMDs) for implementing virtual reality and/or augmented reality.

The display device 10 according to one or more embodiments includes a display panel 100, a heat dissipation layer 200, a circuit board 300, a timing controller 400, and a power supply unit 500.

The display panel 100 may have a shape similar to a rectangular shape in a plan view. For example, the display panel 100 may have a shape similar to a rectangular shape, in a plan view, having short sides in a first direction DR1 and long sides in a second direction DR2 crossing the first direction DR1. In the display panel 100, a corner where the short side in the first direction DR1 and the long side in the second direction DR2 meet may be rounded with a suitable curvature (e.g., a predetermined curvature) or right-angled. A shape of the display panel 100 in a plan view is not limited to the rectangular shape, and may be a shape similar to other polygonal shapes, a circular shape, or an elliptical shape. A shape of the display device 10 in a plan view may follow the shape of the display panel 100 in a plan view, but the present disclosure is not limited thereto.

The display panel 100 may include a display area DAA that displays an image and a non-display area NDA that does not display an image, as illustrated in FIG. 2.

The display area DAA includes a plurality of pixels PX, a plurality of scan lines SL, a plurality of emission control lines EL, and a plurality of data lines DL.

The plurality of pixels PX may be arranged in a matrix form along the first direction DR1 and the second direction DR2. For example, the plurality of pixels PX may be arranged along rows and columns of a matrix along the first direction DR1 and the second direction DR2. The plurality of scan lines SL and the plurality of emission control lines EL may extend in the first direction DR1 and may be disposed along the second direction DR2. The plurality of data lines DL may extend in the second direction DR2 and may be disposed along the first direction DR1.

The plurality of scan lines SL includes a plurality of write scan lines GWL, a plurality of control scan lines GCL, and a plurality of bias scan lines GBL. The plurality of emission control lines EL include a plurality of first emission control lines EL1 and a plurality of second emission control lines EL2.

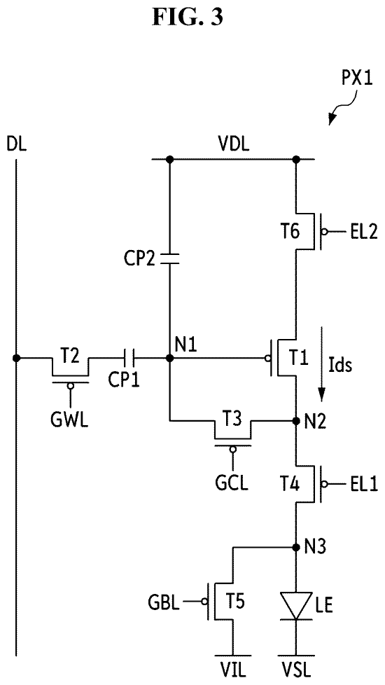

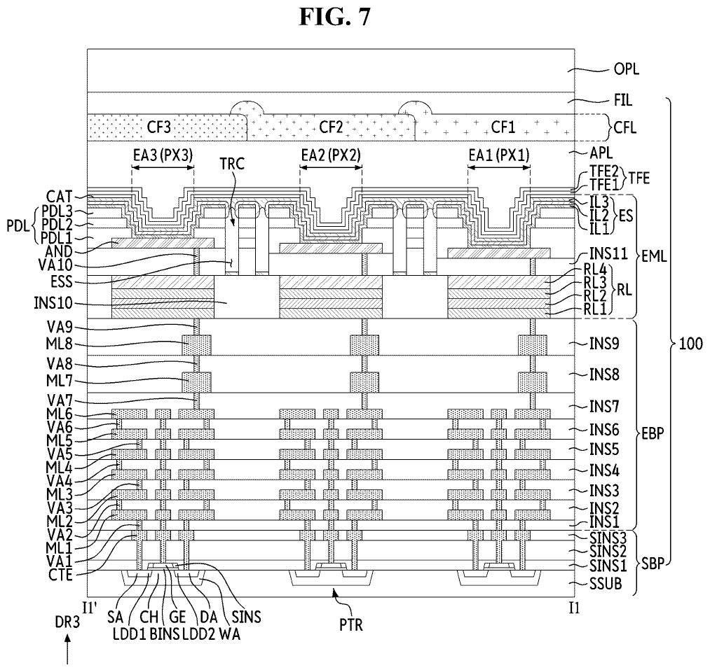

A plurality of unit pixels UPX may include a plurality of pixels PX1, PX2, and PX3. The plurality of pixels PX1, PX2, and PX3 may include a plurality of pixel transistors as illustrated in FIG. 3, and the plurality of pixel transistors may be formed by a semiconductor process and disposed on a semiconductor substrate SSUB (see FIG. 7). For example, a plurality of pixel transistors of a data driver 700 may be formed as complementary metal oxide semiconductor (CMOS).

Each of the plurality of pixels PX1, PX2, and PX3 may be connected to one of the plurality of write scan lines GWL, one of the plurality of control scan lines GCL, one of the plurality of bias scan lines GBL, one of the plurality of first emission control lines EL1, one of the plurality of second emission control lines EL2, and one of the plurality of data lines DL. Each of the plurality of pixels PX1, PX2, and PX3 may receive a data voltage of the data line DL according to a write scan signal of the write scan line GWL, and allow a light emitting element to emit light according to the data voltage.

The non-display area NDA includes a scan driver 610, an emission driver 620, and a data driver 700.

The scan driver 610 includes a plurality of scan transistors, and the emission driver 620 includes a plurality of light emitting transistors. The plurality of scan transistors and the plurality of light emitting transistors may be formed by a semiconductor process and formed on a semiconductor substrate SSUB (see FIG. 7). For example, the plurality of scan transistors and the plurality of light emitting transistors may be formed as CMOS. It has been illustrated in FIG. 2 that the scan driver 610 is disposed on the left side of the display area DAA and the emission driver 620 is disposed on the right side of the display area DAA, but the present disclosure is not limited thereto. For example, the scan drivers 610 and the emission drivers 620 may be disposed on both the left and right sides of the display area DAA.

The scan driver 610 may include a write scan signal output unit 611, a control scan signal output unit 612, and a bias scan signal output unit 613. Each of the write scan signal output unit 611, the control scan signal output unit 612, and the bias scan signal output unit 613 may receive a scan timing control signal SCS from the timing controller 400. The write scan signal output unit 611 may generate write scan signals according to the scan timing control signal SCS of the timing controller 400 and sequentially output the write scan signals to the write scan lines GWL. The control scan signal output unit 612 may generate control scan signals according to the scan timing control signal SCS and sequentially output the control scan signals to the control scan lines GCL. The bias scan signal output unit 613 may generate bias scan signals according to the scan timing control signal SCS and sequentially output the bias scan signals to the bias scan lines GBL.

The emission driver 620 includes a first emission control driver 621 and a second emission control driver 622. Each of the first emission control driver 621 and the second emission control driver 622 may receive an emission timing control signal ECS from the timing controller 400. The first emission control driver 621 may generate first emission control signals according to the emission timing control signal ECS and sequentially output the first emission control signals to the first emission control lines EL1. The second emission control driver 622 may generate second emission control signals according to the emission timing control signal ECS and sequentially output the second emission control signals to the second emission control lines EL2.

The data driver 700 may include a plurality of data transistors, and the plurality of data transistors may be formed by a semiconductor process and formed on a semiconductor substrate SSUB (see FIG. 7). For example, the plurality of data transistors may be formed as CMOS.

The data driver 700 may receive digital video data DATA and a data timing control signal DCS from the timing controller 400. The data driver 700 converts the digital video data DATA into analog data voltages according to the data timing control signal DCS and outputs the analog data voltages to the data lines DL. In this case, the pixels PX1, PX2, and PX3 may be selected by the write scan signals of the scan driver 610, and the data voltages may be supplied to the selected pixels PX1, PX2, and PX3.

The heat dissipation layer 200 may overlap the display panel 100 in a third direction DR3, which is a thickness direction of the display panel 100. The heat dissipation layer 200 may be disposed on one surface, for example, a rear surface, of the display panel 100. The heat dissipation layer 200 serves to dissipate heat generated from the display panel 100. The heat dissipation layer 130 may include a layer made of graphite or metal such as silver (Ag), copper (Cu), and/or aluminum (AI) having high thermal conductivity.

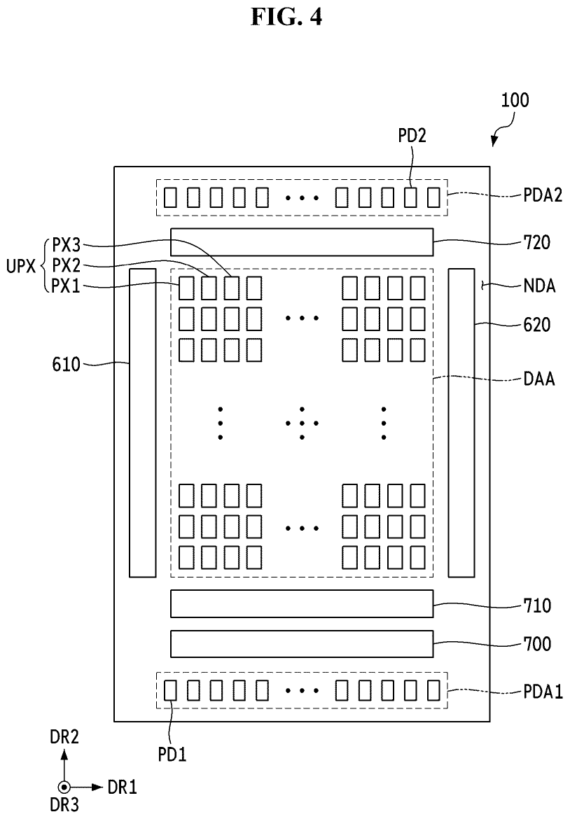

The circuit board 300 may be electrically connected to a plurality of first pads PD1 (see FIG. 4) of a first pad unit PDA1 (see FIG. 4) of the display panel 100 using a conductive adhesive member such as an anisotropic conductive film. The circuit board 300 may be a flexible printed circuit board (FPCB) or a flexible film having a flexible material. It has been illustrated in FIG. 1 that the circuit board 300 is unbent, but the circuit board 300 may be bent. In this case, one end of the circuit board 300 may be disposed on the rear surface of the display panel 100 and/or a rear surface of the heat dissipation layer 200. One end of the circuit board 300 may be an end opposite to the other end of the circuit board 300 connected to the plurality of first pads PD1 (see FIG. 4) of the first pad unit PDA1 (see FIG. 4) of the display panel 100 using the conductive adhesive member.

The timing controller 400 may receive digital video data DATA and timing signals from the outside. The timing controller 400 may generate the scan timing control signal SCS, the emission timing control signal ECS, and the data timing control signal DCS for controlling the display panel 100 according to the timing signals. The timing controller 400 may output the scan timing control signal SCS to the scan driver 610 and output the emission timing control signal ECS to the emission driver 620. The timing controller 400 may output the digital video data DATA and the data timing control signal DCS to the data driver 700.

The power supply unit 500 may generate a plurality of panel driving voltages according to an external source voltage. For example, the power supply unit 500 may generate a common voltage VSS, a driving voltage VDD, and an initialization voltage VINT and supply the common voltage VSS, the driving voltage VDD, and the initialization voltage VINT to the display panel 100. The common voltage VSS, the driving voltage VDD, and the initialization voltage VINT will be described later with reference to FIG. 3.

Each of the timing controller 400 and the power supply unit 500 may be formed as an integrated circuit (IC) and attached to one surface of the circuit board 300. In this case, the scan timing control signal SCS, the emission timing control signal ECS, the digital video data DATA, and the data timing control signal DCS of the timing controller 400 may be supplied to the display panel 100 through the circuit board 300. In addition, the common voltage VSS, the driving voltage VDD, and the initialization voltage VINT of the power supply unit 500 may be supplied to the display panel 100 through the circuit board 300.

Alternatively, each of the timing controller 400 and the power supply unit 500 may be disposed in the non-display area NDA of the display panel 100, similar to the scan driver 610, the emission driver 620, and the data driver 700. In this case, the timing controller 400 may include a plurality of timing transistors, and the power supply unit 500 may include a plurality of power transistors. The plurality of timing transistors and the plurality of power transistors may be formed by a semiconductor process and formed on a semiconductor substrate SSUB (see FIG. 7). For example, the plurality of timing transistors and the plurality of power transistors may be formed as CMOS. Each of the timing controller 400 and the power supply unit 500 may be disposed between the data driver 700 and the first pad unit PDA1 (see FIG. 4).

FIG. 3 is an equivalent circuit diagram of a first pixel according to one or more embodiments.

Referring to FIG. 3, a first pixel PX1 may be connected to a write scan line GWL, a control scan line GCL, a bias scan line GBL, a first emission control line EL1, a second emission control line EL2, and a data line DL. In addition, the first pixel PX1 may be connected to a common voltage line VSL to which a common voltage VSS corresponding to a low potential voltage is applied, a driving voltage line VDL to which a driving voltage VDD corresponding to a high potential voltage is applied, and an initialization voltage line VIL to which an initialization voltage VINT is applied. That is, the common voltage line VSL may be a low potential voltage line, the driving voltage line VDL may be a high potential voltage line, and the initialization voltage line VIL may be an initialization voltage line. In this case, the common voltage VSS may be a voltage lower than the initialization voltage VINT. The driving voltage VDD may be a voltage higher than the initialization voltage VINT.

The first pixel PX1 includes a plurality of transistors T1 to T6, a light emitting element LE, a first capacitor CP1, and a second capacitor CP2.

The light emitting element LE emits light according to a driving current Ids flowing through a channel of a first transistor T1. An amount of light emitted from the light emitting element LE may be proportional to the driving current Ids. The light emitting element LE may be disposed between a fourth transistor T4 and the common voltage line VSL. A first electrode of the light emitting element LE may be connected to a drain electrode of the fourth transistor T4, and a second electrode of the light emitting element LE may be connected to the common voltage line VSL. The first electrode of the light emitting element LE may be an anode electrode, and the second electrode of the light emitting element LE may be a cathode electrode. The light emitting element LE may be an organic light emitting diode (OLED) including a first electrode, a second electrode, and an organic light emitting layer disposed between the first electrode and the second electrode, but the present disclosure is not limited thereto. For example, the light emitting element LE may be an inorganic light emitting element including a first electrode, a second electrode, and an inorganic semiconductor disposed between the first electrode and the second electrode, and in this case, the light emitting element LE may be a micro light emitting diode.

The first transistor T1 may be a driving transistor controlling a source-drain current Ids (hereinafter referred to as a “driving current”) flowing between a source electrode and a drain electrode according to a voltage applied to a gate electrode thereof. The first transistor T1 includes the gate electrode connected to a first node N1, the source electrode connected to a drain electrode of a sixth transistor T6, and the drain electrode connected to a second node N2.

A second transistor T2 may be disposed between one electrode of the first capacitor CP1 and the data line DL. The second transistor T2 is turned on by a write scan signal of the write scan line GWL to connect one electrode of the first capacitor CP1 to the data line DL. For this reason, a data voltage of the data line DL may be applied to one electrode of the first capacitor CP1. The second transistor T2 includes a gate electrode connected to the write scan line GWL, a source electrode connected to the data line DL, and a drain electrode connected to one electrode of the first capacitor CP1.

A third transistor T3 may be disposed between the first node N1 and the second node N2. The third transistor T3 is turned on by a control scan signal of the control scan line GCL to connect the first node N1 to the second node N2. For this reason, the gate electrode and the drain electrode of the first transistor T1 are connected to each other, and thus, the first transistor T1 may operate like a diode (e.g., the first transistor T1 may be diode-connected). The third transistor T3 includes a gate electrode connected to the control scan line GCL, a source electrode connected to the second node N2, and a drain electrode connected to the first node N1.

The fourth transistor T4 may be connected between the second node N2 and a third node N3. The fourth transistor T4 is turned on by a first emission control signal of the first emission control line EL1 to connect the second node N2 to the third node N3. For this reason, the driving current of the first transistor T1 may be supplied to the light emitting element LE. The fourth transistor T4 includes a gate electrode connected to the first emission control line EL1, a source electrode connected to the second node N2, and the drain electrode connected to the third node N3.

A fifth transistor T5 may be disposed between the third node N3 and the initialization voltage line VIL. The fifth transistor T5 is turned on by a bias scan signal of the bias scan line GBL to connect the third node N3 to the initialization voltage line VIL. For this reason, the initialization voltage VINT of the initialization voltage line VIL may be applied to the first electrode of the light emitting element LE. The fifth transistor T5 includes a gate electrode connected to the bias scan line GBL, a source electrode connected to the third node N3, and a drain electrode connected to the initialization voltage line VIL.

The sixth transistor T6 may be disposed between the source electrode of the first transistor T1 and the driving voltage line VDL. The sixth transistor T6 is turned on by a second emission control signal of the second emission control line EL2 to connect the source electrode of the first transistor T1 to the driving voltage line VDL. For this reason, the driving voltage VDD of the driving voltage line VDL may be applied to the source electrode of the first transistor T1. The sixth transistor T6 includes a gate electrode connected to the second emission control line EL2, a source electrode connected to the driving voltage line VDL, and the drain electrode connected to the source electrode of the first transistor T1.

The first capacitor CP1 is formed between the first node N1 and the drain electrode of the second transistor T2. The first capacitor CP1 includes one electrode connected to the drain electrode of the second transistor T2 and the other electrode connected to the first node N1.

The second capacitor CP2 is formed between the gate electrode of the first transistor T1 (e.g., the first node N1) and the driving voltage line VDL. The second capacitor CP2 includes one electrode connected to the gate electrode of the first transistor T1 and the other electrode connected to the driving voltage line VDL.

The first node N1 is a contact point between the gate electrode of the first transistor T1, the drain electrode of the third transistor T3, the other electrode of the first capacitor CP1, and one electrode of the second capacitor CP2. The second node N2 is a contact point between the drain electrode of the first transistor T1, the source electrode of the third transistor T3, and the source electrode of the fourth transistor T4. The third node N3 is a contact point between the drain electrode of the fourth transistor T4, the source electrode of the fifth transistor T5, and the first electrode of the light emitting element LE.

Each of the first to sixth transistors T1 to T6 may be a metal oxide semiconductor field effect transistor (MOSFET). For example, each of the first to sixth transistors T1 to T6 may be a P-type MOSFET, but the present disclosure is not limited thereto. Each of the first to sixth transistors T1 to T6 may be an N-type MOSFET. Alternatively, some of the first to sixth transistors T1 to T6 may be P-type MOSFETs, and the others of the first to sixth transistors T1 to T6 may be N-type MOSFETs.

It has been illustrated in FIG. 3 that the first pixel PX1 includes six transistors T1 to T6 and two capacitors CP1 and CP2, but an equivalent circuit diagram of the first pixel PX1 is not limited to that illustrated in FIG. 3. For example, the numbers of transistors and capacitors of the first pixel PX1 are not limited to those illustrated in FIG. 3.

In addition, an equivalent circuit diagram of a second pixel PX2 and an equivalent circuit diagram of a third pixel PX3 may be substantially the same as the equivalent circuit diagram of the first pixel PX1 described with reference to FIG. 3. Therefore, a description of the equivalent circuit diagram of the second pixel PX2 and the equivalent circuit diagram of the third pixel PX3 is omitted in the present disclosure.

FIG. 4 is a layout diagram illustrating an example of a display panel according to one or more embodiments.

Referring to FIG. 4, the display area DAA of the display panel 100 according to one or more embodiments includes a plurality of pixels PX arranged in a matrix form. The non-display area NDA of the display panel 100 according to one or more embodiments includes a scan driver 610, an emission driver 620, a data driver 700, a first distribution circuit 710, a second distribution circuit 720, a first pad unit PDA1, and a second pad unit PDA2.

The scan driver 610 may be disposed on a first side of the display area DAA, and the emission driver 620 may be disposed on a second side of the display area DAA. For example, the scan driver 610 may be disposed on one side of the display area DAA in the first direction DR1, and the emission driver 620 may be disposed on the other side of the display area DAA in the first direction DR1. That is, the scan driver 610 may be disposed on the left side of the display area DAA, and the emission driver 620 may be disposed on the right side of the display area DAA. However, an exemplary embodiment of the present disclosure is not limited thereto, and the scan drivers 610 and the emission drivers 620 may be disposed on both the first and second sides of the display area DAA.

The first pad unit PDA1 may include a plurality of first pads PD1 connected to pads or bumps of the circuit board 300 through a conductive adhesive member. The first pad unit PDA1 may be disposed on a third side of the display area DAA. For example, the first pad unit PDA1 may be disposed on one side of the display area DAA in the second direction DR2.

The first pad unit PDA1 may be disposed outside the data driver 700 in the second direction DR2. That is, the first pad unit PDA1 may be disposed closer to an edge of the display panel 100 than the data driver 700 is.

The second pad unit PDA2 may include a plurality of second pads PD2 corresponding to inspection pads that inspect whether or not the display panel 100 operates normally. The plurality of second pads PD2 may be connected to a jig or a probe pin or connected to a circuit board for inspection in an inspection process. The circuit board for inspection may be a printed circuit board (PCB) made of a rigid material or a flexible printed circuit board (FPCB) made of a flexible material.

The first distribution circuit 710 distributes data voltages applied through the first pad unit PDA1 to a plurality of data lines DL. For example, the first distribution circuit 710 may distribute data voltages applied through one first pad PD1 of the first pad unit PDA1 to P data lines DL (P is a positive integer of 2 or more), and for this reason, the number of first pads PD1 may be reduced. The first distribution circuit 710 may be disposed on the third side of the display area DAA of the display panel 100. For example, the first distribution circuit 710 may be disposed on one side of the display area DAA in the second direction DR2. That is, the first distribution circuit 710 may be disposed on the lower side of the display area DAA.

The second distribution circuit 720 distributes signals applied through the second pad unit PDA2 to the scan driver 610, the emission driver 620, and the data lines DL. The second pad unit PDA2 and the second distribution circuit 720 may be components for inspecting an operation of each of the pixels PX of the display area DAA. The second distribution circuit 720 may be disposed on a fourth side of the display area DAA of the display panel 100. For example, the second distribution circuit 720 may be disposed on the other side of the display area DAA in the second direction DR2. That is, the second distribution circuit 720 may be disposed on the upper side of the display area DAA.

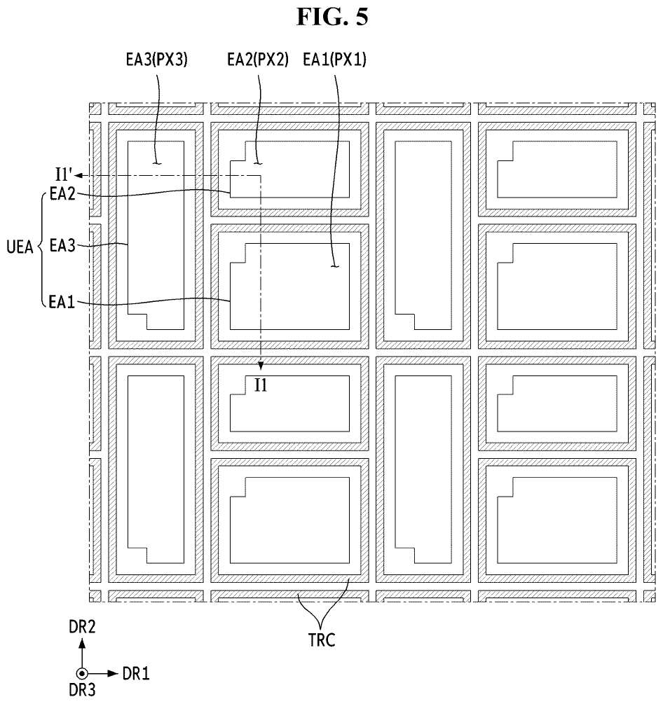

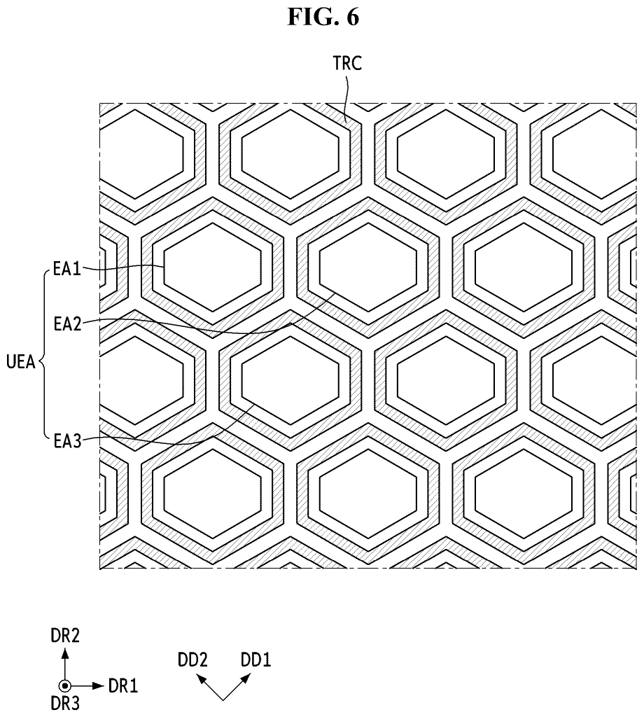

FIGS. 5 and 6 are layout diagrams illustrating one or more embodiments of a display area of FIG. 4.

Referring to FIGS. 5 and 6, each of the plurality of unit pixels UPX includes a first emission area EA1 that is an emission area of the first pixel PX1, a second emission area EA2 that is an emission area of the second pixel PX2, and a third emission area EA3 that is an emission area of the third pixel PX3. In other words, the unit pixel UPX may include a unit emission area UEA, and this unit emission area UEA includes the above-described first emission area EA1, second emission area EA2, and third emission area EA3.

Referring to FIGS. 5 and 6, each of the plurality of unit pixels UPX includes a first emission area EA1 that is an emission area of the first pixel PX1, a second emission area EA2 that is an emission area of the second pixel PX2, and a third emission area EA3 that is an emission area of the third pixel PX3.

Each of the first emission area EA1, the second emission area EA2, and the third emission area EA3 may have a polygonal shape, a circular shape, an elliptical shape, or an irregular shape in a plan view.

A maximum length of the third emission area EA3 in the first direction DR1 may be smaller than a maximum length of the first emission area EA1 in the first direction DR1 and a maximum length of the second emission area EA2 in the first direction DR1. The maximum length of the first emission area EA1 in the first direction DR1 and the maximum length of the second emission area EA2 in the first direction DR1 may be substantially the same as each other.

A maximum length of the third emission area EA3 in the second direction DR2 may be greater than a maximum length of the first emission area EA1 in the second direction DR2 and a maximum length of the second emission area EA2 in the second direction DR2. The maximum length of the first emission area EA1 in the second direction DR2 may be greater than the maximum length of the second emission area EA2 in the second direction DR2. The maximum length of the first emission area EA1 in the second direction DR2 may be smaller than the maximum length of the third emission area EA3 in the second direction DR2.

Each of the first emission area EA1, the second emission area EA2, and the third emission area EA3 may have a hexagonal shape including six straight lines, in a plan view, as illustrated in FIGS. 5 and 6, but the present disclosure is not limited thereto. Each of the first emission area EA1, the second emission area EA2, and the third emission area EA3 may have polygonal shapes other than the hexagonal shape, a circular shape, an elliptical shape, or an irregular shape in a plan view.

As illustrated in FIG. 5, in each of the plurality of pixels PX, the second emission area EA2 and the third emission area EA3 may neighbor to each other in the first direction DR1. In addition, the first emission area EA1 and the third emission area EA3 may neighbor to each other in the first direction DR1. In addition, the first emission area EA1 and the second emission area EA2 may neighbor to each other in the second direction DR2. An area of the first emission area EA1, an area of the second emission area EA2, and an area of the third emission area EA3 may be different from each other.

Alternatively, as illustrated in FIG. 6, the first emission area EA1 and the second emission area EA2 may neighbor to each other in the first direction DR1, but the second emission area EA2 and the third emission area EA3 may neighbor to each other in a first diagonal direction DD1, and the first emission area EA1 and the third emission area EA3 may neighbor to each other in a second diagonal direction DD2. The first diagonal direction DD1 is a direction between the first direction DR1 and the second direction DR2 and may refer to a direction inclined by 45° with respect to the first direction DR1 and the second direction DR2, and the second diagonal direction DD2 may be a direction orthogonal to the first diagonal direction DD1.

The first emission area EA1 may emit light of a first color, the second emission area EA2 may emit light of a second color, and the third emission area EA3 may emit light of a third color. Here, the light of the first color may be light of a blue wavelength band, the light of the second color may be light of a green wavelength band, and the light of the third color may be light of a red wavelength band. For example, the blue wavelength band may indicate that a main peak wavelength of the light is included in a wavelength band of approximately 370 nm to 460 nm, the green wavelength band may indicate that a main peak wavelength of the light is included in a wavelength band of approximately 480 nm to 560 nm, and the red wavelength band may indicate that a main peak wavelength of the light is included in a wavelength band of approximately 600 nm and 750 nm.

It has been illustrated in FIGS. 5 and 6 that each of the plurality of unit pixels UPX includes three emission areas EA1, EA2, and EA3, but the present disclosure is not limited thereto. That is, each of the plurality of unit pixels UPX may also include four emission areas.

In addition, an arrangement of the emission areas of the plurality of unit pixels UPX is not limited to those illustrated in FIGS. 5 and 6. For example, the emission areas of the plurality of unit pixels UPX may be disposed in a stripe structure in which the emission areas are arranged along the first direction DR1, a PENTILE® structure in which the emission areas have a diamond arrangement, or a hexagonal structure in which emission areas having a hexagonal shape in a plan view are arranged as illustrated in FIG. 6. PENTILE® is a registered trademark of Samsung Display Co., Ltd., Republic of Korea.

FIG. 7 is a cross-sectional view illustrating an example of the display panel taken along the line I1-I1′ of FIG. 5.

The display device may include a display panel 100 and an optical layer OPL, as illustrated in FIG. 7.

The display panel 100 may include a semiconductor backplane SBP, a light emitting element backplane EBP, a display element layer EML, an encapsulation layer TFE, a color filter layer CFL, and a filling layer FIL.

The semiconductor backplane SBP may include a semiconductor substrate SSUB including a plurality of pixel transistors PTR, a plurality of semiconductor insulating films covering the plurality of pixel transistors PTR, and a plurality of contact terminals CTE electrically connected to the plurality of pixel transistors PTR, respectively. The plurality of pixel transistors PTR may be the first to sixth transistors T1 to T6 described with reference to FIG. 3.

The semiconductor substrate SSUB may be a silicon substrate, a germanium substrate, and/or a silicon-germanium substrate. The semiconductor substrate SSUB may be a substrate doped with first-type impurities. A plurality of well regions WA may be disposed in an upper surface of the semiconductor substrate SSUB. The plurality of well regions WA may be regions doped with second-type impurities. The second-type impurities may be different from the first-type impurities described above. For example, when the first-type impurities are p-type impurities, the second-type impurities may be n-type impurities. Alternatively, when the first-type impurities are n-type impurities, the second-type impurities may be p-type impurities.

Each of the plurality of well regions WA includes a source region SA corresponding to a source electrode of the pixel transistor PTR, a drain region DA corresponding to a drain electrode of the pixel transistor PTR, and a channel region CH disposed between the source region SA and the drain region DA.

A bottom insulating film BINS may be disposed between a gate electrode GE and the well region WA. Side surface insulating films SINS may be disposed on side surfaces of the gate electrode GE. The side surface insulating films SINS may be disposed on the bottom insulating film BINS.

Each of the source region SA and the drain region DA may be a region doped with the first-type impurities. The gate electrode GE of the pixel transistor PTR may overlap the well region WA in the third direction DR3. The channel region CH may overlap the gate electrode GE in the third direction DR3. The source region SA may be disposed on one side of the gate electrode GE, and the drain region DA may be disposed on the other side of the gate electrode GE.

Each of the plurality of well regions WA further includes a first low-concentration impurity region LDD1 disposed between the channel region CH and the source region SA and a second low-concentration impurity region LDD2 disposed between the channel region CH and the drain region DA. The first low-concentration impurity region LDD1 may be a region having a lower impurity concentration than the source region SA due to the bottom insulating film BINS. The second low-concentration impurity region LDD2 may be a region having a lower impurity concentration than the drain region DA due to the bottom insulating film BINS. A distance between the source region SA and the drain region DA may increase by the first low-concentration impurity region LDD1 and the second low-concentration impurity region LDD2. Therefore, a length of the channel region CH of each of the pixel transistors PTR may increase, and thus, punch-through and hot carrier phenomena caused by a short channel may be reduced or prevented.

A first semiconductor insulating film SINS1 may be disposed on the semiconductor substrate SSUB and the pixel transistor PTR. The first semiconductor insulating film SINS1 may be formed as a silicon carbonitride (SiCN) and/or silicon oxide (SiOₓ)-based inorganic film, but the present disclosure is not limited thereto.

A second semiconductor insulating film SINS2 may be disposed on the first semiconductor insulating film SINS1. The second semiconductor insulating film SINS2 may be formed as a silicon oxide (SiOₓ)-based inorganic film, but the present disclosure is not limited thereto.

The plurality of contact terminals CTE may be disposed on the second semiconductor insulating film SINS2. Each of the plurality of contact terminals CTE may be connected to the gate electrode GE, the source region SA, or the drain region DA of each of the pixel transistors PTR through a hole penetrating through the first semiconductor insulating film SINS1 and the second semiconductor insulating film INS2. Each of the plurality of contact terminals CTE may be made of copper (Cu), aluminum (AI), tungsten (W), molybdenum (Mo), chromium (Cr), gold (Au), titanium (Ti), nickel (Ni), and/or neodymium (Nd), and/or alloys thereof.

A third semiconductor insulating film SINS3 may be disposed on side surfaces of each of the plurality of contact terminals CTE. An upper surface of each of the plurality of contact terminals CTE may be exposed without being covered by the third semiconductor insulating film SINS3. The third semiconductor insulating film SINS3 may be formed as a silicon oxide (SiOₓ)-based inorganic film, but the present disclosure is not limited thereto.

The semiconductor substrate SSUB may be replaced with a glass substrate and/or a polymer resin substrate such as a polyimide substrate. In this case, thin film transistors may be disposed on the glass substrate and/or the polymer resin substrate. The glass substrate may be a rigid substrate that is not bent, and the polymer resin substrate may be a flexible substrate that may be bent and/or curved.

The light emitting element backplane EBP includes a plurality of conductive layers ML1 to ML8, a plurality of vias VA1 to VA9, and a plurality of insulating films INS1 to INS9. In the light emitting element backplane EBP, the plurality of insulating films INS1 to INS9 may be disposed between first to eighth conductive layers ML1 to ML8.

The first to eighth conductive layers ML1 to ML8 serve to implement a circuit of the first pixel PX1 illustrated in FIG. 3 by connecting the plurality of contact terminals CTE exposed from the semiconductor backplane SBP to each other. For example, only the first to sixth transistors T1 to T6 are formed in the semiconductor backplane SBP, and the connection between the first to sixth transistors T1 to T6 and the formation of the first capacitor CP1 and the second capacitor CP2 are performed through the first to eighth conductive layers ML1 to ML8. In addition, the connection between a drain region corresponding to the drain electrode of the fourth transistor T4, a source region corresponding to the source electrode of the fifth transistor T5, and the first electrode of the light emitting element LE is also performed through the first to eighth conductive layers ML1 to ML8.

A first insulating film INS1 may be disposed on the semiconductor backplane SBP. Each of first vias VA1 may penetrate through the first film INS1 to be connected to the contact terminal CTE exposed from the semiconductor backplane SBP. Each of the first conductive layers ML1 may be disposed on the first insulating film INS1 and may be connected to the first via VA1.

A second insulating film INS2 may be disposed on the first insulating film INS1 and the first conductive layers ML1. Each of second vias VA2 may penetrate through the second insulating film INS2 to be connected to the exposed first conductive layer ML1. Each of the second conductive layers ML2 may be disposed on the second insulating film INS2 and may be connected to the second via VA2.

A third insulating film INS3 may be disposed on the second insulating film INS2 and the second conductive layers ML2. Each of third vias VA3 may penetrate through the third insulating film INS3 to be connected to the exposed second conductive layer ML2. Each of the third conductive layers ML3 may be disposed on the third insulating film INS3 and may be connected to the third via VA3.

A fourth insulating film INS4 may be disposed on the third insulating film INS3 and the third conductive layer ML3. Each of fourth vias VA4 may penetrate through the fourth insulating film INS4 to be connected to the exposed third conductive layer ML3. Each of the fourth conductive layers ML4 may be disposed on the fourth insulating film INS4 and may be connected to the fourth via VA4.

A fifth insulating film INS4 may be disposed on the fourth insulating film INS4 and the fourth conductive layers ML4. Each of fifth vias VA5 may penetrate through the fifth film INS5 to be connected to the exposed fourth conductive layer ML4. Each of the fifth conductive layers ML5 may be disposed on the fifth insulating film INS5 and may be connected to the fifth via VA5.

A sixth insulating film INS6 may be disposed on the fifth insulating film INS5 and the fifth conductive layer ML5. Each of sixth vias VA6 may penetrate through the sixth insulating film INS6 to be connected to the exposed fifth conductive layer ML5. Each of the sixth conductive layers ML6 may be disposed on the sixth insulating film INS6 and may be connected to the sixth via VA6.

A seventh insulating film INS7 may be disposed on the sixth insulating film INS6 and the sixth conductive layer ML6. Each of seventh vias VA7 may penetrate through the seventh insulating film INS7 to be connected to the exposed sixth conductive layer ML6. Each of the seventh conductive layers ML7 may be disposed on the seventh insulating film INS7 and may be connected to the seventh via VA7.

An eighth insulating film INS8 may be disposed on the seventh insulating film INS7 and the seventh conductive layer ML7. Each of eighth vias VA8 may penetrate through the eighth insulating film INS8 to be connected to the exposed seventh conductive layer ML7. Each of the eighth conductive layers ML8 may be disposed on the eighth insulating film INS8 and may be connected to the eighth via VA8.

The first to eighth conductive layers ML1 to ML8 and the first to eighth vias VA1 to VA8 may be made of substantially the same material. Each of the first to eighth conductive layers ML1 to ML8 and the first to eighth vias VA1 to VA8 may be made of copper (Cu), aluminum (AI), tungsten (W), molybdenum (Mo), chromium (Cr), gold (Au), titanium (Ti), nickel (Ni), and/or neodymium (Nd), and/or alloys thereof. The first to eighth vias VA1 to VA8 may be made of substantially the same material. The first to eighth insulating films INS1 to INS8 may be formed as silicon oxide (SiOₓ)-based inorganic films, but the present disclosure is not limited thereto.

Each of a thickness of the first conductive layer ML1, a thickness of the second conductive layer ML2, a thickness of the third conductive layer ML3, a thickness of the fourth conductive layer ML4, a thickness of the fifth conductive layer ML5, and a thickness of the sixth conductive layer ML6 may be greater than each of a thickness of the first via VA1, a thickness of the second via VA2, a thickness of the third via VA3, a thickness of the fourth via VA4, a thickness of the fifth via VA5, and a thickness of the sixth via VA6. Each of the thickness of the second conductive layer ML2, the thickness of the third conductive layer ML3, the thickness of the fourth conductive layer ML4, the thickness of the fifth conductive layer ML5, and the thickness of the sixth conductive layer ML6 may be greater than the thickness of the first conductive layer ML1. The thickness of the second conductive layer ML2, the thickness of the third conductive layer ML3, the thickness of the fourth conductive layer ML4, the thickness of the fifth conductive layer ML5, and the thickness of the sixth conductive layer ML6 may be substantially the same as each other. For example, the thickness of the first conductive layer ML1 may be approximately 1360 Å, each of the thickness of the second conductive layer ML2, the thickness of the third conductive layer ML3, the thickness of the fourth conductive layer ML4, the thickness of the fifth conductive layer ML5, and the thickness of the sixth conductive layer ML6 may be approximately 1440 Å, and each of the thickness of the first via VA1, the thickness of the second via VA2, the thickness of the third via VA3, the thickness of the fourth via VA4, the thickness of the fifth via VA5, and the thickness of the sixth via VA6 may be approximately 1150 Å.

Each of a thickness of the seventh conductive layer ML7 and a thickness of the eighth conductive layer ML8 may be greater than each of the thickness of the first conductive layer ML1, the thickness of the second conductive layer ML2, the thickness of the third conductive layer ML3, the thickness of the fourth conductive layer ML4, the thickness of the fifth conductive layer ML5, and the thickness of the sixth conductive layer ML6. Each of the thickness of the seventh conductive layer ML7 and the eighth conductive layer ML8 may be greater than each of a thickness of the seventh via VA7 and a thickness of the eighth via VA8. Each of the thickness of the seventh via VA7 and the thickness of the eighth via VA8 may be greater than each of the thickness of the first via VA1, the thickness of the second via VA2, the thickness of the third via VA3, the thickness of the fourth via VA4, the thickness of the fifth via VA5, and the thickness of the sixth via VA6. The thickness of the seventh conductive layer ML7 and the thickness of the eighth conductive layer ML8 may be substantially the same as each other. For example, each of the thickness of the seventh conductive layer ML7 and the thickness of the eighth conductive layer ML8 may be approximately 9000 Å. Each of the thickness of the seventh via VA7 and the thickness of the eighth via VA8 may be approximately 6000 Å.

A ninth insulating film INS9 may be disposed on the eighth insulating film INS8 and the eighth conductive layer ML8. The ninth insulating film INS9 may be formed as a silicon oxide (SiOₓ)-based inorganic film, but the present disclosure is not limited thereto.

Each of ninth vias VA9 may penetrate through the ninth insulating film INS9 to be connected to the exposed eighth conductive layer ML8. Each of the ninth vias VA9 may be made of copper (Cu), aluminum (Al), tungsten (W), molybdenum (Mo), chromium (Cr), gold (Au), titanium (Ti), nickel (Ni), and/or neodymium (Nd), and/or alloys thereof. A thickness of the ninth via VA9 may be approximately 16500 Å.

The display element layer EML may be disposed on the light emitting element backplane EBP. The display element layer EML may include a reflective electrode layer RL, tenth and eleventh insulating films INS10 and INS11, tenth vias VA10, light emitting elements LE each including a first electrode AND, a light emitting stack ES, and a second electrode CAT, a pixel defining film PDL, and a plurality of trenches TRC.

The reflective electrode layer RL may be disposed on the ninth insulating film INS9. The reflective electrode layer RL may include one or more reflective electrodes RL1, RL2, RL3, and RL4. For example, the reflective electrode layer RL may include first to fourth reflective electrodes RL1, RL2, RL3, and RL4 as illustrated in FIG. 7.

Each of the first reflective electrodes RL1 may be disposed on the ninth insulating film INS9 and may be connected to the ninth via VA9. Each of the first reflective electrodes RL1 may be made of copper (Cu), aluminum (AI), tungsten (W), molybdenum (Mo), chromium (Cr), gold (Au), titanium (Ti), nickel (Ni), and/or neodymium (Nd), and/or alloys thereof. For example, each of the first reflective electrodes RL1 may include titanium nitride (TiN).

Each of the second reflective electrodes RL2 may be disposed on the first reflective electrode RL1. Each of the second reflective electrodes RL2 may be made of copper (Cu), aluminum (AI), tungsten (W), molybdenum (Mo), chromium (Cr), gold (Au), titanium (Ti), nickel (Ni), and/or neodymium (Nd), and/or alloys thereof. For example, each of the second reflective electrodes RL2 may include aluminum (Al).

Each of the third reflective electrodes RL3 may be disposed on the second reflective electrode RL2. Each of the third reflective electrodes RL3 may be made of copper (Cu), aluminum (AI), tungsten (W), molybdenum (Mo), chromium (Cr), gold (Au), titanium (Ti), nickel (Ni), and/or neodymium (Nd), and/or alloys thereof. For example, each of the third reflective electrodes RL3 may include titanium nitride (TiN).

Each of the fourth reflective electrodes RL4 may be disposed on the third reflective electrode RL3. Each of the fourth reflective electrodes RL4 may be made of copper (Cu), aluminum (AI), tungsten (W), molybdenum (Mo), chromium (Cr), gold (Au), titanium (Ti), nickel (Ni), and/or neodymium (Nd), and/or alloys thereof. For example, each of the fourth reflective electrodes RL4 may include titanium (Ti).

Because the second reflective electrodes RL2 are electrodes substantially reflecting light from the light emitting elements LE, in one or more embodiments, a thickness of the second reflective electrode RL2 may be greater than a thickness of the first reflective electrode RL1, a thickness of the third reflective electrode RL3, and a thickness of the fourth reflective electrode RL4. For example, each of the thickness of the first reflective electrode RL1, the third reflective electrode RL3, and the fourth reflective electrode RL4 may be approximately 100 Å, and the thickness of the second reflective electrode RL2 may be approximately 850 Å. However, in one or more other embodiments, the fourth reflective electrodes RL4 are electrodes substantially reflecting light from the light emitting elements LE, and a thickness of the fourth reflective electrode RL4 may be greater than a thickness of the first reflective electrode RL1, a thickness of the second reflective electrode RL2, and a thickness of the third reflective electrode RL3.

The tenth insulating film INS10 may be disposed on the ninth insulating film INS9. The tenth insulating film INS10 may be disposed between the reflective electrode layers RL adjacent to each other in a horizontal direction (e.g., the first direction DR1 and/or the second direction DR2). In one or more embodiments, the tenth insulating film INS10 may be disposed on the reflective electrode layer RL in the third pixel PX3. The tenth insulating film INS10 may be formed as a silicon oxide (SiOₓ)-based inorganic film, but the present disclosure is not limited thereto.

The eleventh insulating film INS11 may be disposed on the tenth insulating film INS10 and the reflective electrode layer RL. The eleventh insulating film INS11 may be formed as a silicon oxide (SiOₓ)-based inorganic film, but the present disclosure is not limited thereto. The tenth insulating film INS10 and the eleventh insulating film INS11 may be optical auxiliary layers through which light reflected by the reflective electrode layer RL from among light emitted from the light emitting elements LE passes.

In order to adjust a resonance distance of the light emitted from the light emitting elements LE in at least one of the first pixel PX1, the second pixel PX2, and the third pixel PX3, in one or more embodiments, the tenth insulating film INS10 and the eleventh insulating film INS11 may not be disposed below the first electrode AND of the first pixel PX1. In one or more embodiments, the first electrode AND of the first pixel PX1 may be directly disposed on the reflective electrode layer RL. As shown in FIG. 7, the eleventh insulating film INS11 may be disposed on the tenth insulating film INS10 and the reflective electrode layer RL of the first pixel PX1, the second pixel PX2, and the third pixel PX3, and may be disposed below the first electrode AND of the first pixel PX1, the second pixel PX2, and the third pixel PX3. However, the thickness of the eleventh insulating film INS11 disposed in the first pixel PX1, the second pixel PX2, and the third pixel PX3, may be different. In one or more embodiments, the tenth insulating film INS10 and the eleventh insulating film INS11 may only be disposed below the first electrode AND of the third pixel PX3.

In summary, a distance between the first electrode AND and the reflective electrode layer RL may be different in each of the first pixel PX1, the second pixel PX2, and the third pixel PX3. That is, in order to adjust a distance from the reflective electrode layer RL to the second electrode CAT according to a main wavelength of light emitted from each of the first pixel PX1, the second pixel PX2, and third the pixel PX3, the presence or absence of the tenth insulating film INS10 and the eleventh insulating film INS11 may be set in each of the first pixel PX1, the second pixel PX2, and the third pixel PX3. For example, it has been illustrated in FIG. 7 that a distance between the first electrode AND and the reflective electrode layer RL in the third pixel PX3 is greater than a distance between the first electrode AND and the reflective electrode layer RL in the second pixel PX2 and a distance between the first electrode AND and the reflective electrode layer RL in the first pixel PX1 and the distance between the first electrode AND and the reflective electrode layer RL in the second pixel PX2 is greater than the distance between the first electrode AND and the reflective electrode layer RL in the first pixel PX1, but the present disclosure is not limited thereto.

Although the tenth insulating film INS10 and the eleventh insulating film INS11 have been illustrated in the present disclosure, in one or more embodiments, a twelfth insulating film disposed below the first electrode AND of the first pixel PX1 may be added. In this case, the eleventh insulating film INS11 and the twelfth insulating film INS12 may be disposed below the first electrode AND of the second pixel PX2, and the tenth insulating film INS10, the eleventh insulating film INS11, and the twelfth insulating film INS12 may be disposed below the first electrode AND of the third pixel PX3.

As shown in FIG. 7, each of the tenth vias VA10 may penetrate through the eleventh insulating film INS11 in the first pixel PX1, the second pixel PX2, and the third pixel PX3 to be connected to the exposed fourth reflective electrode RL4. In one or more other embodiments, each of the tenth vias VA10 may penetrate through the tenth insulating film INS10 and/or the eleventh insulating film INS11 in the second pixel PX2 and the third pixel PX3 to be connected to the exposed fourth reflective electrode RL4. Each of the tenth vias VA10 may be made of copper (Cu), aluminum (Al), tungsten (W), molybdenum (Mo), chromium (Cr), gold (Au), titanium (Ti), nickel (Ni), and/or neodymium (Nd), and/or alloys thereof.

A thickness of the tenth via VA10 in the first pixel PX1 may be smaller than a thickness of the tenth via VA10 in the second pixel PX2, and a thickness of the tenth via VA10 in the second pixel PX2 may be smaller than a thickness of the tenth via VA10 in the third pixel PX3.

In one or more embodiments, the first electrode AND of each of the light emitting elements LE may be disposed on the tenth insulating film INS10 or the eleventh insulating film INS11 and may be connected to the tenth via VA10. The first electrode AND of each of the light emitting elements LE may be connected to the drain region DA or the source region SA of the pixel transistor PTR through the tenth via VA10, the first to fourth reflective electrodes RL1 to RL4, the first to ninth vias VA1 to VA9, the first to eighth conductive layers ML1 to ML8, and the contact terminal CTE. The first electrode AND of each of the light emitting elements LE may be made of copper (Cu), aluminum (Al), tungsten (W), molybdenum (Mo), chromium (Cr), gold (Au), titanium (Ti), nickel (Ni), and/or neodymium (Nd), and/or alloys thereof. For example, the first electrode AND of each of the light emitting elements LE may be made of titanium nitride (TiN).

The pixel defining film PDL may be disposed on a partial area of the first electrode AND of each of the light emitting elements LE. The pixel defining film PDL may cover an edge of the first electrode AND of each of the light emitting elements LE. The pixel defining film PDL serves to partition the first emission areas EA1, the second emission areas EA2, and the third emission areas EA3.

The first emission area EA1 may be defined as an area where the first electrode AND, the light emitting stack ES, and the second electrode CAT are sequentially stacked in the first pixel PX1 to emit light. The second emission area EA2 may be defined as an area where the first electrode AND, the light emitting stack ES, and the second electrode CAT are sequentially stacked in the second pixel PX2 to emit light. The third emission area EA3 may be defined as an area where the first electrode AND, the light emitting stack ES, and the second electrode CAT are sequentially stacked in the third pixel PX3 to emit light.

The pixel defining film PDL may include first to third pixel defining films PDL1, PDL2, and PDL3. The first pixel defining film PDL1 may be disposed on the edge of the first electrode AND of each of the light emitting elements LE, the second pixel defining film PDL2 may be disposed on the first pixel defining film PDL1, and the third pixel defining film PDL3 may be disposed on the second pixel defining film PDL2. The first pixel defining film PDL1, the second pixel defining film PDL2, and the third pixel defining film PDL3 may be formed as silicon oxide (SiOₓ)-based inorganic films, but the present disclosure is not limited thereto. Each of a thickness of the first pixel defining film PDL1, a thickness of the second pixel defining film PDL2, and a thickness of the third pixel defining film PDL3 may be approximately 500 Å.

When the first pixel defining film PDL1, the second pixel defining film PDL2, and the third pixel defining film PDL3 are formed as one pixel defining film, a height of the one pixel defining film increases, such that a first encapsulation inorganic film TFE1 may be disconnected due to step coverage. The step coverage refers to a ratio of a degree at which a thin film is coated on an inclined portion to a degree at which a thin film is coated on a flat portion. The lower the step coverage, the more likely it is that the thin film will be disconnected at the inclined portion.

Therefore, in order to prevent the first encapsulation inorganic film TFE1 from being disconnected due to the step coverage, the first pixel defining film PDL1, the second pixel defining film PDL2, and the third pixel defining film PDL3 may have a cross-sectional structure with a step having a staircase shape. For example, a width of the first pixel defining film PDL1 may be greater than a width of the second pixel defining film PDL2 and a width of the third pixel defining film PDL3, and the width of the second pixel defining film PDL2 may be greater than the width of the third pixel defining film PDL3. The width of the first pixel defining film PDL1 refers to a length of the first pixel defining film PDL1 in the horizontal direction defined by the first direction DR1 and/or the second direction DR2.

Each of the plurality of trenches TRC may penetrate through the first pixel defining film PDL1, the second pixel defining film PDL2, and the third pixel defining film PDL3. In addition, each of the plurality of trenches TRC may penetrate through the eleventh insulating film INS11. In each of the plurality of trenches TRC, the tenth insulating film INS10 may have a shape in which a portion thereof is trenched.

At least one trench TRC may be disposed between the pixels PX1, PX2, and PX3 neighboring to each other. It has been illustrated in FIG. 7 that two trenches TRC are disposed between the pixels PX1, PX2, and PX3 neighboring to each other, but the present disclosure is not limited thereto.

The light emitting stack ES may include a plurality of stack layers. It has been illustrated in FIG. 7 that the light emitting stack ES has a three-tandem structure including a first stack layer IL1, a second stack layer IL2, and a third stack layer IL3, but the present disclosure is not limited thereto. For example, the light emitting stack ES may have a two-tandem structure including two intermediate layers.

In the three-tandem structure, the light emitting stack ES may have a tandem structure including a plurality of stack layers IL1, IL2, and IL3 emitting different light. For example, the light emitting stack ES may include a first stack layer IL1 emitting light of a first color, a second stack layer IL2 emitting light of a third color, and a third stack layer IL3 emitting light of a second color. The first stack layer IL1, the second stack layer IL2, and the third stack layer IL3 may be sequentially stacked.

The first stack layer IL1 may have a structure in which a first hole transporting layer, a first organic light emitting layer emitting the light of the first color, and a first electron transporting layer are sequentially stacked. The second stack layer IL2 may have a structure in which a second hole transporting layer, a second organic light emitting layer emitting the light of the third color, and a second electron transporting layer are sequentially stacked. The third stack layer IL3 may have a structure in which a third hole transporting layer, a third organic light emitting layer emitting the light of the second color, and a third electron transporting layer are sequentially stacked.

A first charge generation layer for supplying charges to the second stack layer IL2 and supplying electrons to the first stack layer IL1 may be disposed between the first stack layer IL1 and the second stack layer IL2. The first charge generation layer may include an N-type charge generation layer supplying electrons to the first stack layer IL1 and a P-type charge generation layer supplying holes to the second stack layer IL2. The N-type charge generation layer may include a dopant of a metal material.

A second charge generation layer for supplying charges to the third stack layer IL3 and supplying electrons to the second stack layer IL2 may be disposed between the second stack layer IL2 and the third stack layer IL3. The second charge generation layer may include an N-type charge generation layer supplying electrons to the second stack layer IL2 and a P-type charge generation layer supplying holes to the third stack layer IL3.

The first stack layer IL1 may be disposed on the first electrodes AND and the pixel defining film PDL, and may be disposed on a bottom surface of each of the trenches TRC. Due to the trenches TRC, the first stack layer IL1 may be disconnected between the pixels PX1, PX2, and PX3 neighboring to each other. The second stack layer IL2 may be disposed on the first stack layer IL1. Due to the trenches TRC, the second stack layer IL2 may be disconnected between the pixels PX1, PX2, and PX3 neighboring to each other. A cavity ESS or an empty space may be disposed between the first stack layer IL1 and the second stack layer IL2. The third stack layer IL3 may be disposed on the second stack layer IL2. The third stack layer IL3 may not be disconnected by the trenches TRC, and may be disposed to cover the second stack layer IL2 in each of the trenches TRC. That is, in the three-tandem structure, each of the plurality of trenches TRC may be a structure for disconnecting the first and second stack layers IL1 and IL2, the first charge generation layer, and the second charge generation layer of the display element layer EML between the pixels PX1, PX2, and PX3 neighboring to each other. In addition, in the two-tandem structure, each of the plurality of trenches TRC may be a structure for disconnecting a charge generation layer disposed between a lower intermediate layer and an upper intermediate layer and the lower intermediate layer.

In order to stably disconnect the first and second stack layers IL1 and IL2 of the display element layer EML between the pixels PX1, PX2, and PX3 neighboring to each other, a height of each of the plurality of trenches TRC may be greater than a height of the pixel defining film PDL. The height of each of the plurality of trenches TRC refers to a length of each of the plurality of trenches TRC in the third direction DR3. The height of the pixel defining film PDL refers to a length of the pixel defining film PDL in the third direction DR3. In order to disconnect the first and second intermediate layers IL1 and IL2 of the display element layer EML between the pixels PX1, PX2, and PX3 neighboring to each other, other structures may exist instead of the trenches TRC. For example, instead of the trenches TRC, partition walls having a reverse tapered shape may be disposed on the pixel defining film PDL.

The number of stack layers IL1, IL2, and IL3 emitting the different light is not limited to that illustrated in FIG. 7. For example, the light emitting stack ES may include two intermediate layers. In this case, any one of the two intermediate layers may be substantially the same as the first stack layer IL1, and the other one of the two intermediate layers may include a second hole transporting layer, a second organic light emitting layer, a third organic light emitting layer, and a second electron transporting layer. In this case, a charge generation layer for supplying electrons to any one intermediate layer and supplying charges to the other intermediate layer may be disposed between the two intermediate layers.

It has been illustrated in FIG. 7 that the first to third stack layers IL1, IL2, and IL3 are all disposed in the first emission area EA1, the second emission area EA2, and the third emission area EA3, but the present disclosure is not limited thereto. For example, the first stack layer IL1 may be disposed in the first emission area EA1, and may not be disposed in the second emission area EA2 and the third emission area EA3. In addition, the second stack layer IL2 may be disposed in the second emission area EA2, and may not be disposed in the first emission area EA1 and the third emission area EA3. In addition, the third stack layer IL3 may be disposed in the third emission area EA3, and may not be disposed on the first emission area EA1 and the second emission area EA2. In this case, the color filter layer CFL (e.g., first to third color filters CF1, CF2, and CF3) may be omitted.

The second electrode CAT may be disposed on the third stack layer IL3. The second electrode CAT may be disposed on the third stack layer IL3 in each of the plurality of trenches TRC. The second electrode CAT may be made of a transparent conductive material (TCO) such as indium tin oxide (ITO) and/or indium zinc oxide (IZO) capable of transmitting light therethrough or a semi-transmissive conductive material such as magnesium (Mg), silver (Ag), and/or an alloy of magnesium (Mg) and/or silver (Ag). When the second electrode CAT is made of the semi-transmissive conductive material, light emission efficiency of each of the first to third pixels PX1, PX2, and PX3 may be increased by a micro cavity.

The encapsulation layer TFE may be disposed on the display element layer EML. The encapsulation layer TFE may include at least one inorganic film TFE1 or TFE2 in order to prevent oxygen and/or moisture from permeating into the display element layer EML. For example, the encapsulation layer TFE may include a first encapsulation inorganic film TFE1 and a second encapsulation inorganic film TFE2.

The first encapsulation inorganic film TFE1 may be disposed on the second electrode CAT. The first encapsulation inorganic film TFE1 may be formed as multiple films in which one or more inorganic films of a silicon nitride (SiNₓ) layer, a silicon oxynitride (SiON) layer, and a silicon oxide (SiOₓ) layer are alternately stacked. The first encapsulation inorganic film TFE1 may be formed by a chemical vapor deposition (CVD) process.

The second encapsulation inorganic film TFE2 may be disposed on the first encapsulation inorganic film TFE1. The second encapsulation inorganic film TFE2 may be formed as a titanium oxide (TiOₓ) layer and/or an aluminum oxide (AlOₓ) layer, but the present disclosure is not limited thereto. The second encapsulation inorganic film TFE2 may be formed by an atomic layer deposition (ALD) process. A thickness of the second encapsulation inorganic film TFE2 may be smaller than a thickness of the first encapsulation inorganic film TFE1.

An organic film APL may be a layer for increasing interfacial adhesive strength between the encapsulation layer TFE and the optical layer OPL. The organic film APL may be an organic film made of an acrylic resin, an epoxy resin, a phenolic resin, a polyamide resin, a polyimide resin, and/or the like.

The color filter layer CFL may be disposed on the organic layer APL. The color filter layer CFL may include a first color filter CF1, a second color filter CF2, and a third color filter CF3.

The first color filter CF1 may overlap the first emission area EA1 of the first pixel PX1. The first color filter CF1 may transmit the light of the first color, that is, the light of the blue wavelength band, therethrough. The blue wavelength band may be approximately 370 nm to 460 nm. Therefore, the first color filter CF1 may transmit the light of the first color from among light emitted from the first emission area EA1 therethrough.

The second color filter CF2 may overlap the second emission area EA2 of the second pixel PX2. The second color filter CF2 may transmit the light of the second color, that is, the light of the green wavelength band, therethrough. The green wavelength band may be approximately 480 nm to 560 nm. Therefore, the second color filter CF2 may transmit the light of the second color from among light emitted from the second emission area EA2 therethrough.

The third color filter CF3 may overlap the third emission area EA3 of the third pixel PX3. The third color filter CF3 may transmit the light of the third color, that is, the light of the red wavelength band, therethrough. The blue wavelength band may be approximately 600 nm to 750 nm. Therefore, the third color filter CF3 may transmit the light of the third color from among light emitted from the third emission area EA3 therethrough.

The filling layer FIL may be disposed on the color filter layer CFL. For example, the filling layer FIL may be disposed on the first color filter CF1, the second color filter CF2, and the third color filter CF3. A step between adjacent color filters may be planarized by the filling layer FIL. The filling layer FIL may have a suitable refractive index (e.g., a predetermined refractive index) so that light travels in the third direction DR3 at an interface between a plurality of color filters CF1, CF2, and CF3 and the filling layer FIL. The filling layer FIL may be an organic film made of an acrylic resin, an epoxy resin, a phenolic resin, a polyamide resin, a polyimide resin, and/or the like.

The optical layer OPL may be disposed on the filling layer FIL. The optical layer OPL may be disposed on the filling layer FIL so as to overlap all of the pixels PX1, PX2, and PX3. For example, the optical layer OPL may be disposed on the filling layer FIL so as to overlap all of the emission areas EA1, EA2, and EA3. In one or more embodiments, the optical layer OPL may be disposed on the filling layer FIL so as to overlap the entirety of the display area DAA of the display panel 100.

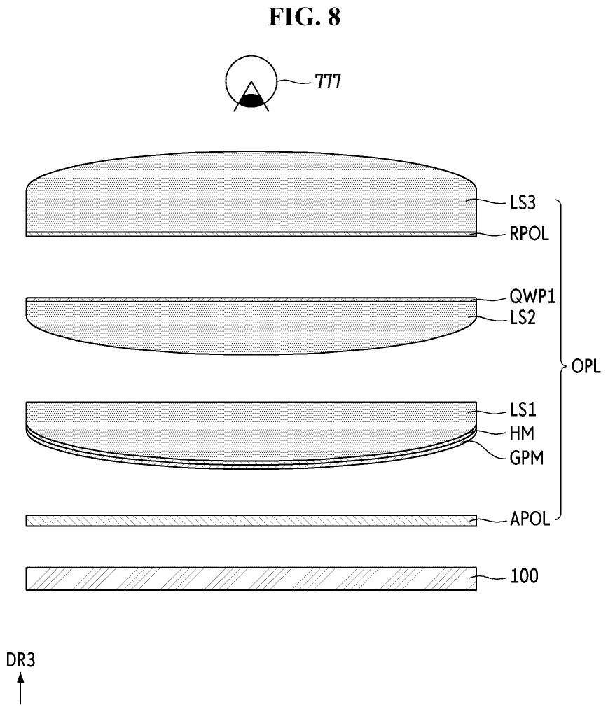

FIG. 8 is a detailed configuration diagram of an optical layer OPL of FIG. 7.

The optical layer OPL may include an absorptive polarization layer APOL, a geometric phase module GPM, a translucent mirror (e.g., a half mirror) HM, a first lens LS1, a second lens LS2, a first phase delay layer QWP1, a reflective polarization layer RPOL, and a third lens LS3, as illustrated in FIG. 8.

The absorptive polarization layer APOL may be disposed on the display panel 100. For example, the absorptive polarization layer APOL may be disposed on the filling layer FIL of the display panel 100. When the filling layer FIL is omitted, the absorptive polarization layer APOL may be disposed on the color filter layer CFL.

The geometric phase module GPM may be disposed on the absorptive polarization layer APOL. The geometric phase module GPM may have a curved shape or a parabolic shape. For example, as illustrated in FIG. 8, in cross-sectional view, the geometric phase module GPM may have a curved shape or a parabolic shape convex toward the display panel 100 or the absorptive polarization layer APOL. In other words, the geometric phase module GPM may have a curved shape or a parabolic shape convex in a direction reverse to the third direction DR3 (hereinafter referred to as a third reverse direction). The geometric phase module GPM may overlap the entire surface of the display panel 100. For example, the geometric phase module GPM may overlap the entirety of the display area DAA of the display panel 100.

The translucent mirror HM may be disposed on the geometric phase module GPM. The translucent mirror HM may have a curved shape. For example, as illustrated in FIG. 8, in cross-sectional view, the translucent mirror HM may have a curved shape or a parabolic shape convex in the third reverse direction. The translucent mirror HM and geometric phase module GPM may be in contact with each other.

The first lens LS1 may be disposed on the translucent mirror HM. The first lens LS1 may be a convex lens convex in the third reverse direction. The first lens LS1 may have a convex surface and a flat surface facing each other in the third direction DR3, and the above-described translucent mirror HM may be in contact with the convex surface of the first lens LS1. A curvature of the above-described translucent mirror HM and a curvature of the above-described geometric phase module GPM may be the same as a curvature of the first lens LS1. However, the present disclosure is not limited thereto, and curvatures of at least two of the translucent mirror HM, the geometric phase module GPM, and the first lens LS1 may be different from each other.

The second lens LS2 may be disposed on the first lens LS1. The second lens LS2 may be a convex lens convex in the third reverse direction. The second lens LS2 may have a convex surface and a flat surface facing each other in the third direction DR3. A curvature of the second lens LS2 may be the same as the curvature of the first lens LS1.

The first phase delay layer QWP1 may be disposed on the second lens LS2. For example, the first phase delay layer QWP1 may be disposed on the flat surface of the second lens LS2. The first phase delay layer QWP1 may be in contact with the flat surface of the second lens LS2. The first phase delay layer QWP1 may be a λ/4 plate (quarter-wave plate).

The reflective polarization layer RPOL may be disposed on the first phase delay layer QWP1.

The third lens LS3 may be disposed on the reflective polarization layer RPOL. The third lens LS3 may be a convex lens convex in the third direction DR3. The third lens LS3 may have a convex surface and a flat surface facing each other in the third direction DR3. A curvature of the third lens LS3 may be the same as the curvature of the first lens LS1. The above-described reflective polarization layer RPOL may be disposed on the flat surface of the third lens LS3. The reflective polarization layer RPOL may be in contact with the flat surface of the third lens LS3.

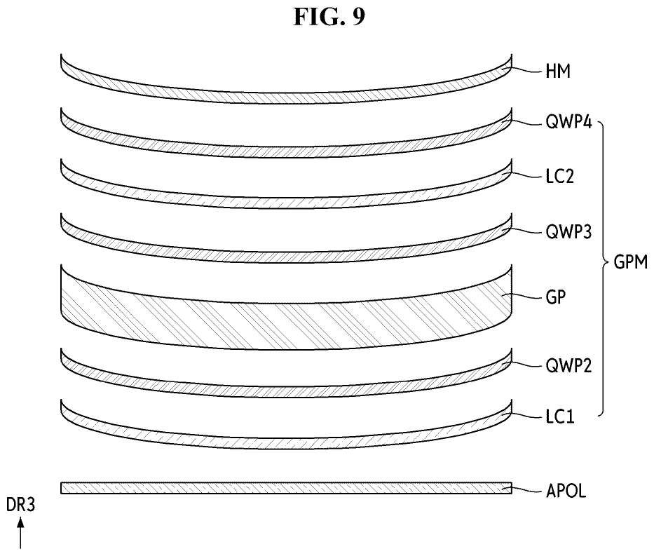

FIG. 9 is a detailed configuration diagram of a geometric phase module GPM of FIG. 8.

The geometric phase module GPM may include a first linear polarization conversion layer LC1, a second phase delay layer QWP2, a geometric phase lens GP, a third phase delay layer QWP3, a second linear polarization conversion layer LC2, and a fourth phase delay layer QWP4, as illustrated in FIG. 9.

According to one or more embodiments, each of the first linear polarization conversion layer LC1, the second phase delay layer QWP2, the geometric phase lens GP, the third phase delay layer QWP3, the second linear polarization conversion layer LC2, and the fourth phase delay layer QWP4 of the geometric phase module GPM may have a curved shape or a parabolic shape. For example, as illustrated in FIG. 9, in cross-sectional view, each of the first linear polarization conversion layer LC1, the second phase delay layer QWP2, the geometric phase lens GP, the third phase delay layer QWP3, the second linear polarization conversion layer LC2, and the fourth phase delay layer QWP4 may have a curved shape or a parabolic shape convex in the third reverse direction toward the display panel 100 or the absorptive polarization layer APOL. In other words, as illustrated in FIG. 9, in cross-sectional view, each of the first linear polarization conversion layer LC1, the second phase delay layer QWP2, the geometric phase lens GP, the third phase delay layer QWP3, the second linear polarization conversion layer LC2, and the fourth phase delay layer QWP4 may have a curved shape or a parabolic shape convex in the third reverse direction. Here, the first linear polarization conversion layer LC1, the second phase delay layer QWP2, the geometric phase lens GP, the third phase delay layer QWP3, the second linear polarization conversion layer LC2, and the fourth phase delay layer QWP4 may have the same curvature.

The first linear polarization conversion layer LC1, the second phase delay layer QWP2, the geometric phase lens GP, the third phase delay layer QWP3, the second linear polarization conversion layer LC2, and the fourth phase delay layer QWP4 of the geometric phase module GPM may overlap the entire surface of the display panel 100. For example, the first linear polarization conversion layer LC1, the second phase delay layer QWP2, the geometric phase lens GP, the third phase delay layer QWP3, the second linear polarization conversion layer LC2, and the fourth phase delay layer QWP4 may overlap the entirety of the display area DAA of the display panel 100.

The first linear polarization conversion layer LC1 may be disposed on the absorptive polarization layer APOL. The first linear polarization conversion layer LC1 may include a liquid crystal panel. For example, the first linear polarization conversion layer LC1 may be a liquid crystal panel including a first polarization layer, a second polarization layer, and a twisted liquid crystal. Here, the twisted nematic liquid crystal may be disposed between the first polarization layer and the second polarization layer. In this case, a transmission axis (or a polarization axis) of the first polarization layer and a transmission axis (or a polarization axis) of the second polarization layer may form an angle of 90°. The first polarization layer of the first linear polarization conversion layer LC1 may face the absorptive polarization layer APOL, and the second polarization layer of the first linear polarization conversion layer LC1 may face the second phase delay layer QWP2. The polarization axis of the first polarization layer of the first linear polarization conversion layer LC1 and a polarization axis of the above-described absorptive polarization layer APOL may have the same direction. An angle between the first polarization layer of the first linear polarization conversion layer LC1 and the polarization axis of the above-described absorptive polarization layer APOL may be 90°. A curvature of the first linear polarization conversion layer LC1 may be the same as the curvature of at least one of the above-described first lens LS1, second lens LS2, and third lens LS3.

The second phase delay layer QWP2 may be disposed on the first linear polarization conversion layer LC1. The second phase delay layer QWP2 may be a λ/4 plate (quarter-wave plate). A curvature of the second phase delay layer QWP2 may be the same as the curvature of at least one of the above-described first lens LS1, second lens LS2, and third lens LS3.

The geometric phase lens GP may be disposed on the second phase delay layer QWP2. The geometric phase lens GP may function as a convex lens or a concave lens depending on a polarization state (or a polarization direction) of light incident thereon. For example, when the light incident on the geometric phase lens GP is light circularly polarized in a clockwise direction, the geometric phase lens GP may function as the convex lens. On the other hand, when the light incident on the geometric phase lens GP is light circularly polarized in a counterclockwise direction, the geometric phase lens GP may function as the concave lens. Accordingly, when the light circularly polarized in the clockwise direction passes through the geometric phase lens GP, the light circularly polarized in the clockwise direction may converge to a focus of the geometric phase lens GP. On the other hand, when the light circularly polarized in the counterclockwise direction passes through the geometric phase lens GP, the light circularly polarized in the counterclockwise direction may be diverged from a virtual focus of the geometric phase lens GP. In addition, the light that has passed through the geometric phase lens GP may have an inverted polarization direction. For example, when the light circularly polarized in the clockwise direction passes through the geometric phase lens GP, the light circularly polarized in the clockwise direction may be converted into a state in which it is circularly polarized in the counterclockwise direction. On the other hand, when the light circularly polarized in the counterclockwise direction passes through the geometric phase lens GP, the light circularly polarized in the counterclockwise direction may be converted into a state in which it is circularly polarized in the clockwise direction. According to one or more embodiments, the geometric phase lens GP may have a cross section with a curved shape. A curvature of the geometric phase lens GP may be the same as the curvature of at least one of the above-described first lens LS1, second lens LS2, and/or third lens LS3.

The third phase delay layer QWP3 may be disposed on the geometric phase lens GP. The third phase delay layer QWP3 may be a λ/4 plate (quarter-wave plate). A curvature of the third phase delay layer QWP3 may be the same as the curvature of at least one of the above-described first lens LS1, second lens LS2, and/or third lens LS3.

The second linear polarization conversion layer LC2 may be disposed on the third phase delay layer QWP3. The second linear polarization conversion layer LC2 may have the same configuration as the above-described first linear polarization conversion layer LC1. A curvature of the second linear polarization conversion layer LC2 may be the same as the curvature of at least one of the above-described first lens LS1, second lens LS2, and third lens LS3.

The fourth phase delay layer QWP4 may be disposed on the second linear polarization conversion layer LC2. For example, the fourth phase delay layer QWP4 may be disposed between the second linear polarization conversion layer LC2 and the above-described translucent mirror HM. A curvature of the fourth phase delay layer QWP4 may be the same as the curvature of at least one of the above-described first lens LS1, second lens LS2, and/or third lens LS3.

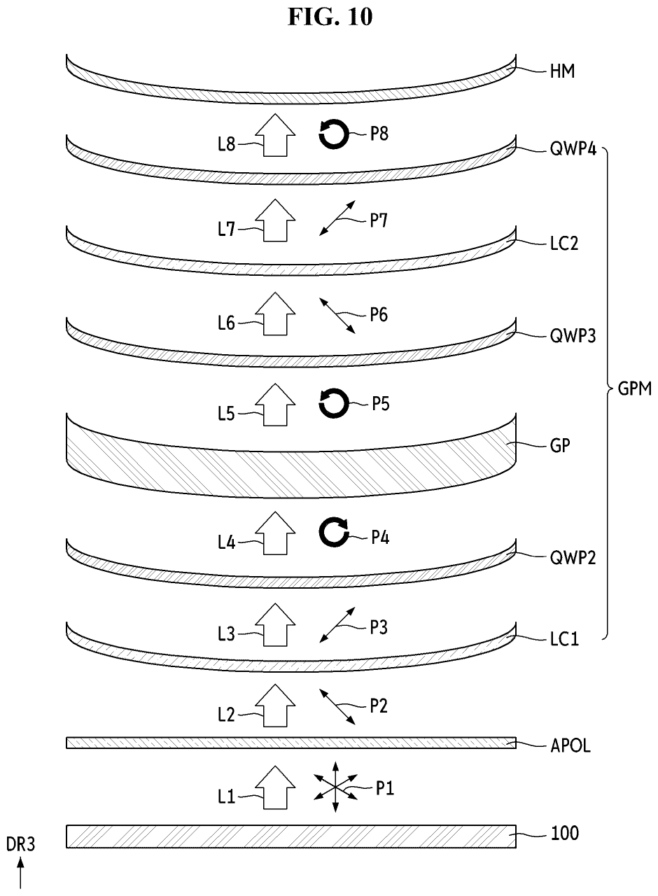

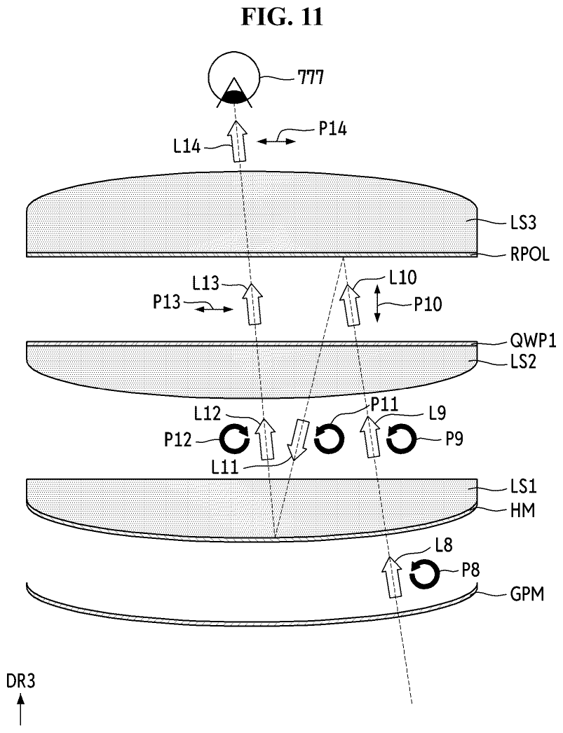

FIGS. 10 and 11 are views for describing a movement path of light in the display device of FIG. 8.

First light L1 from the display panel 100 may be light in a state P1 in which it is not polarized. For example, the first light L1 may be light emitted from the light emitting element. In one or more embodiments, the first light L1 emitted from the light emitting element may be provided to the absorptive polarization layer APOL through the color filter layer CFL.

The first light L1 from the display panel 100 may be incident on the absorptive polarization layer APOL. Light in a direction parallel to a transmission axis (or polarization axis) of the absorptive polarization layer APOL from among the first light L1 may pass through the absorptive polarization layer APOL. For example, second light L2 that has passed through the absorptive polarization layer APOL from among the first light L1 may have a state P2 in which it is linearly polarized in a direction of +45°. In other words, the second light L2 may be light linearly polarized in the direction of +45°.

The second light L2 may be incident on the first linear polarization conversion layer LC1. The second light L2 may be converted into third light L3 while passing through the first linear polarization conversion layer LC1. For example, the third light L3 may have a state P3 in which it is linearly polarized in a direction of −45°. In other words, the third light L3 may be light linearly polarized in the direction of −45°. An angle between a polarization direction of the third light L3 and a polarization direction of the second light L2 may be 90°. In other words, the polarization direction of the third light L3 and the polarization direction of the second light L2 may form an angle of 90°.

The third light L3 may be incident on the second phase delay layer QWP2. The third light L3 may be converted into fourth light L4 while passing through the second phase delay layer QWP2. For example, the fourth light L4 may have a state P4 in which it is circularly polarized in a right direction (or the clockwise direction). In other words, the fourth light L4 may be light circularly polarized in the clockwise direction.

The fourth light L4 may be incident on the geometric phase lens GP. The fourth light L4 may be converted into fifth light L5 while passing through the geometric phase lens GP. For example, the fifth light L5 may have a state P5 in which it is circularly polarized in a left direction (or the counterclockwise direction). In other words, the fifth light L5 may be light circularly polarized in the counterclockwise direction.

The fifth light L5 may be incident on the third phase delay layer QWP3. The fifth light L5 may be converted into sixth light L6 while passing through the third phase delay layer QWP3. For example, the sixth light L6 may have a state P6 in which it is linearly polarized in the direction of +45°. In other words, the sixth light L6 may be light linearly polarized in the direction of +45°.

The sixth light L6 may be incident on the second linear polarization conversion layer LC2. The sixth light L6 may be converted into seventh light L7 while passing through the second linear polarization conversion layer LC2. For example, the seventh light L7 may have a state P7 in which it is linearly polarized in the direction of −45°. In other words, the seventh light L7 may be light linearly polarized in the direction of −45°. An angle between a polarization direction of the seventh light L7 and a polarization direction of the sixth light L6 may be 90°. In other words, the polarization direction of the seventh light L7 and the polarization direction of the sixth light L6 may form an angle of 90°.

The seventh light L7 may be incident on the fourth phase delay layer QWP4. The seventh light L7 may be converted into eighth light L8 while passing through the fourth phase delay layer QWP4. For example, the eighth light L8 may have a state P8 in which it is circularly polarized in the left direction (or the counterclockwise direction). In other words, the eighth light L8 may be light circularly polarized in the counterclockwise direction.

The eighth light L8 may be incident on the translucent mirror HM. For example, as illustrated in FIG. 11, the eighth light L8 from the geometric phase module GPM may be incident on the translucent mirror HM. Some of the eighth light L8 may be reflected by the translucent mirror HM and incident on the fourth phase delay layer QWP4, and the other ones of the eighth light L8 may pass through the translucent mirror HM. The eighth light L8 may sequentially pass through the translucent mirror HM and the first lens LS1. Ninth light L9 that has sequentially passed through the translucent mirror HM and the first lens LS1 may have the same polarization state P9 as the eighth light L8. For example, the ninth light L9 may have a state P9 in which it is circularly polarized in the left direction (or the counterclockwise direction). In other words, the ninth light L9 may be light circularly polarized in the counterclockwise direction.

The ninth light L9 may pass through the second lens LS2 and may be incident on the first phase delay layer QWP1. The ninth light L9 may be converted into tenth light L10 while passing through the first phase delay layer QWP1. For example, the tenth light L10 may have a state P10 in which it is linearly polarized in a direction of 90°.

The tenth light L10 may be incident on the reflective polarization layer RPOL. The tenth light L10 may be reflected by the reflective polarization layer RPOL. For example, a polarization direction of the tenth light L10 crosses a transmission axis of the reflective polarization layer RPOL, and thus, the tenth light L10 may be reflected by the reflective polarization layer RPOL.

The tenth light L10 reflected by the reflective polarization layer RPOL may be incident on the first phase delay layer QWP1. The tenth light L10 may be converted into eleventh light L11 while passing through the first phase delay layer QWP1. For example, the eleventh light L11 may have a state P11 in which it is circularly polarized in the left direction (or the counterclockwise direction). In other words, the eleventh light L11 may be light circularly polarized in the counterclockwise direction. The eleventh light L11 may pass through the second lens LS2.

The eleventh light L11 that has passed through the second lens LS2 may be incident on the first lens LS1. The eleventh light L11 that has passed through the first lens LS1 may be incident on the translucent mirror HM. The eleventh light L11 may be reflected by the translucent mirror HM and converted into twelfth light L12. For example, the twelfth light L12 may have a state P12 in which it is circularly polarized in the right direction (or the clockwise direction). In other words, the twelfth light L12 may be light circularly polarized in the clockwise direction. The twelfth light L12 reflected by the translucent mirror HM may pass through the first lens LS1 and may be incident on the second lens LS2.

The twelfth light L12 incident on the second lens LS2 may pass through the second lens LS2 and may be incident on the first phase delay layer QWP1. The twelfth light L12 may be converted into thirteenth light L13 while passing through the first phase delay layer QWP1. For example, the thirteenth light L13 may have a state P13 in which it is linearly polarized in a direction of 0°. An angle between a polarization direction of the thirteenth light L13 and the polarization direction of the tenth light L10 may be 90°. In other words, the polarization direction of the thirteenth light L13 and the polarization direction of the tenth light L10 may form an angle of 90°. Accordingly, the thirteenth light L13 may pass through the reflective polarization layer RPOL. For example, the polarization direction of the thirteenth light L13 is parallel to the transmission axis of the reflective polarization layer RPOL, and thus, the thirteenth light L13 may pass through the reflective polarization layer RPOL.

The thirteenth light L13 that has passed through the reflective polarization layer RPOL may be incident on a user's eye 777 through the third lens LS3. For example, fourteenth light L14 that has sequentially passed through the reflective polarization layer RPOL and the third lens LS3 may have a state in which it is linearly polarized in the direction of 0°, and may be incident on the user's eyes.

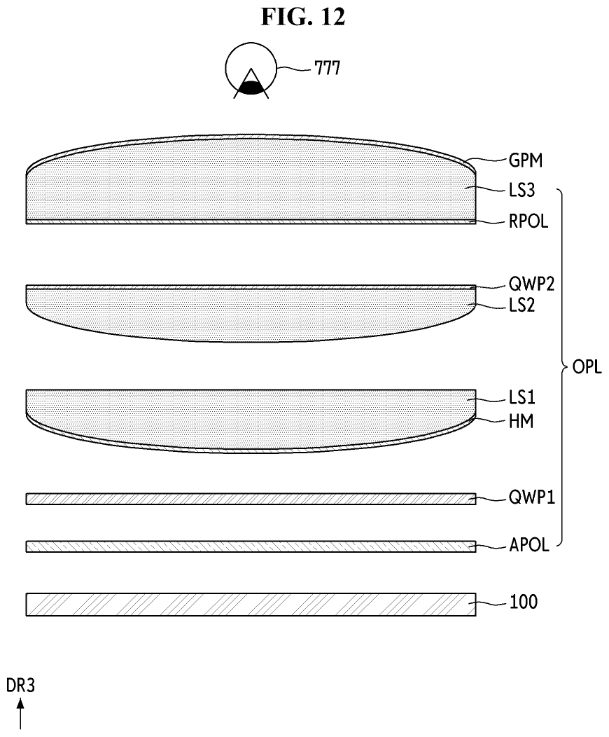

FIG. 12 is a detailed configuration diagram of another example embodiment of the optical layer OPL of FIG. 7.

The optical layer OPL may include an absorptive polarization layer APOL, a translucent mirror HM, a first lens LS1, a second lens LS2, a first phase delay layer QWP1, a second phase delay layer QWP2, a reflective polarization layer RPOL, a third lens LS3, and a geometric phase module GPM, as illustrated in FIG. 12.

The absorptive polarization layer APOL may be disposed on the display panel 100. For example, the absorptive polarization layer APOL may be disposed on the filling layer FIL of the display panel 100. When the filling layer FIL is omitted, the absorptive polarization layer APOL may be disposed on the color filter layer CFL.

The first phase delay layer QWP1 may be disposed on the absorptive polarization layer APOL. The first phase delay layer QWP1 may be a λ/4 plate (quarter-wave plate).

The translucent mirror HM may be disposed on the first phase delay layer QWP1. The translucent mirror HM may have a curved shape. The translucent mirror HM of FIG. 12 is substantially the same as the translucent mirror HM described above with reference to FIG. 8, and thus, reference is made to FIG. 8 and the related description in relation to the translucent mirror HM of FIG. 12.

The first lens LS1 may be disposed on the translucent mirror HM. The first lens LS1 of FIG. 12 is substantially the same as the first lens LS1 described above with reference to FIG. 8, and thus, reference is made to FIG. 8 and the related description in relation to the first lens LS1 of FIG. 12.

The second lens LS2 may be disposed on the first lens LS1. The second lens LS2 of FIG. 12 is substantially the same as the second lens LS2 described above with reference to FIG. 8, and thus, reference is made to FIG. 8 and the related description in relation to the second lens LS2 of FIG. 12.

The second phase delay layer QWP2 may be disposed on the second lens LS2. The second phase delay layer QWP2 of FIG. 12 is substantially the same as the first phase delay layer QWP1 described above with reference to FIG. 8, and thus, reference is made to FIG. 8 and the related description in relation to the second phase delay layer QWP2 of FIG. 12.

The reflective polarization layer RPOL may be disposed on the second phase delay layer QWP2. The reflective polarization layer RPOL of FIG. 12 is substantially the same as the reflective polarization layer RPOL described above with reference to FIG. 8, and thus, reference is made to FIG. 8 and the related description in relation to the reflective polarization layer RPOL of FIG. 12.

The third lens LS3 may be disposed on the reflective polarization layer RPOL. The third lens LS3 of FIG. 12 is substantially the same as the third lens LS3 described above with reference to FIG. 8, and thus, reference is made to FIG. 8 and the related description in relation to the third lens LS3 of FIG. 12.

The geometric phase module GPM may be disposed on the third lens LS3. The geometric phase module GPM may have a curved shape or a parabolic shape. For example, as illustrated in FIG. 12, in cross-sectional view, the geometric phase module GPM may have a curved shape or a parabolic shape convex in a direction reverse to a direction toward the display panel 100 or the third lens LS3. In other words, as illustrated in FIG. 12, in cross-sectional view, the geometric phase module GPM may have a curved shape or a parabolic shape convex in the third direction DR3.

The third lens LS3 may have a convex surface and a flat surface facing each other in the third direction DR3, and the above-described geometric phase module GPM may be in contact with the convex surface of the third lens LS3. In addition, the above-described reflective polarization layer RPOL may be in contact with the flat surface of the third lens LS3.

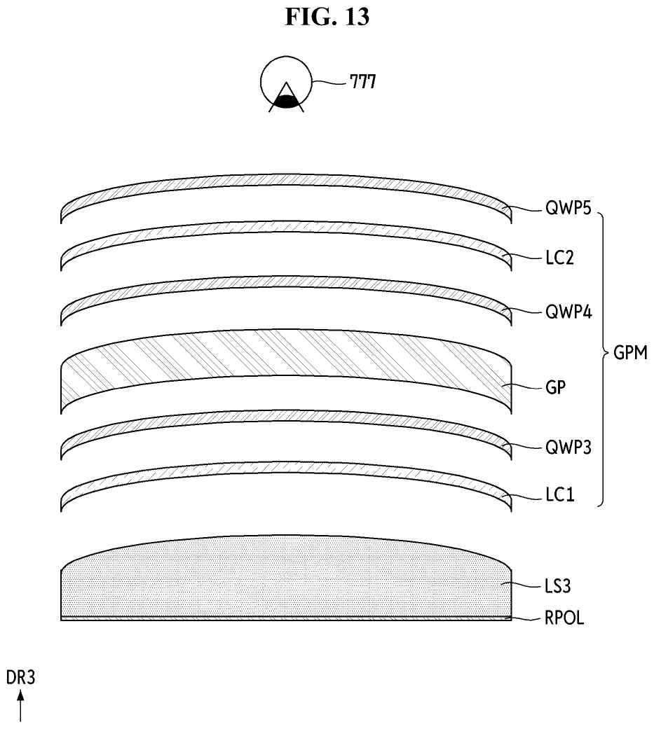

FIG. 13 is a detailed configuration diagram of a geometric phase module GPM of FIG. 12.

The geometric phase module GPM may include a first linear polarization conversion layer LC1, a third phase delay layer QWP3, a geometric phase lens GP, a fourth phase delay layer QWP4, a second linear polarization conversion layer LC2, and a fifth phase delay layer QWP5, as illustrated in FIG. 13.

According to one or more embodiments, each of the first linear polarization conversion layer LC1, the third phase delay layer QWP3, the geometric phase lens GP, the fourth phase delay layer QWP4, the second linear polarization conversion layer LC2, and the fifth phase delay layer QWP5 of the geometric phase module GPM may have a curved shape or a parabolic shape. For example, as illustrated in FIG. 13, in cross-sectional view, each of the first linear polarization conversion layer LC1, the third phase delay layer QWP3, the geometric phase lens GP, the fourth phase delay layer QWP4, the second linear polarization conversion layer LC2, and the fifth phase delay layer QWP5 may have a curved shape or a parabolic shape convex in the direction reverse to the direction toward the display panel 100 or the third lens LS3. In other words, as illustrated in FIG. 13, in cross-sectional view, each of the first linear polarization conversion layer LC1, the third phase delay layer QWP3, the geometric phase lens GP, the fourth phase delay layer QWP4, the second linear polarization conversion layer LC2, and the fifth phase delay layer QWP5 may have a curved shape or a parabolic shape convex in the third direction DR3. Here, the first linear polarization conversion layer LC1, the third phase delay layer QWP3, the geometric phase lens GP, the fourth phase delay layer QWP4, the second linear polarization conversion layer LC2, and the fifth phase delay layer QWP5 may have the same curvature.

The first linear polarization conversion layer LC1 may be disposed on the third lens LS3. For example, the first linear polarization conversion layer LC1 may be disposed on the convex surface of the third lens LS3. The first linear polarization conversion layer LC1 of FIG. 13 is substantially the same as the first linear polarization conversion layer LC1 described above with reference to FIG. 9, and thus, reference is made to FIG. 9 and the related description in relation to the first linear polarization conversion layer LC1 of FIG. 13. In one or more embodiments, a first polarization layer of the first linear polarization conversion layer LC1 of FIG. 13 may face the third lens LS3, and a second polarization layer of the first linear polarization conversion layer LC1 may face the third phase delay layer QWP3.

The third phase delay layer QWP3 may be disposed on the first linear polarization conversion layer LC1. The third phase delay layer QWP3 of FIG. 13 is substantially the same as the second phase delay layer QWP2 described above with reference to FIG. 9, and thus, reference is made to FIG. 9 and the related description in relation to the third phase delay layer QWP3 of FIG. 13.

The geometric phase lens GP may be disposed on the third phase delay layer QWP3. The geometric phase lens GP of FIG. 13 is substantially the same as the geometric phase lens GP described above with reference to FIG. 9, and thus, reference is made to FIG. 9 and the related description in relation to the geometric phase lens GP of FIG. 13.

The fourth phase delay layer QWP4 may be disposed on the geometric phase lens GP. The fourth phase delay layer QWP4 of FIG. 13 is substantially the same as the third phase delay layer QWP3 described above with reference to FIG. 9, and thus, reference is made to FIG. 9 and the related description in relation to the fourth phase delay layer QWP4 of FIG. 13.

The second linear polarization conversion layer LC2 may be disposed on the fourth phase delay layer QWP4. The second linear polarization conversion layer LC2 of FIG. 13 is substantially the same as the second linear polarization conversion layer LC2 described above with reference to FIG. 9, and thus, reference is made to FIG. 9 and the related description in relation to the second linear polarization conversion layer LC2 of FIG. 13.

The fifth phase delay layer QWP5 may be disposed on the second linear polarization conversion layer LC2. The fifth phase delay layer QWP5 of FIG. 13 is substantially the same as the fourth phase delay layer QWP4 described above with reference to FIG. 9, and thus, reference is made to FIG. 9 and the related description in relation to the fifth phase delay layer QWP5 of FIG. 13.

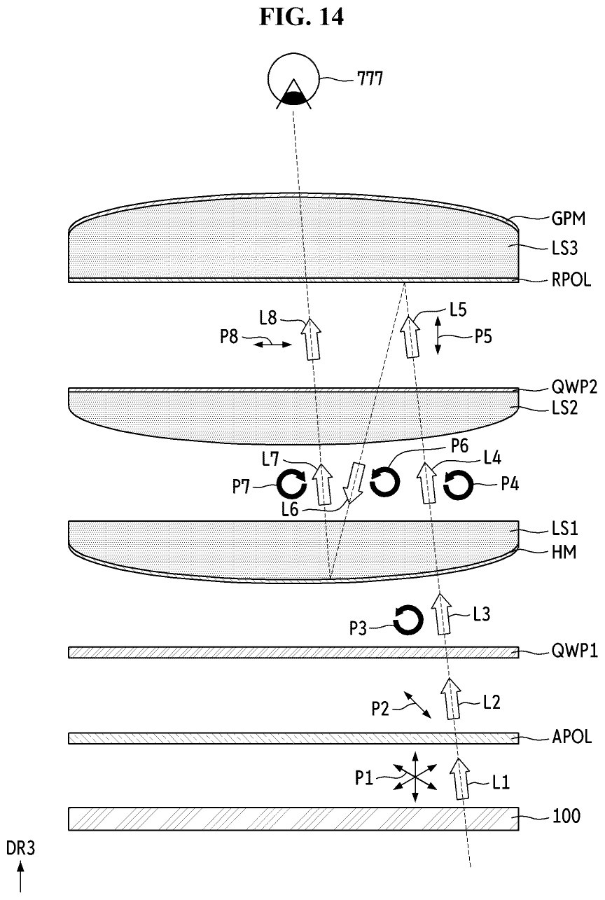

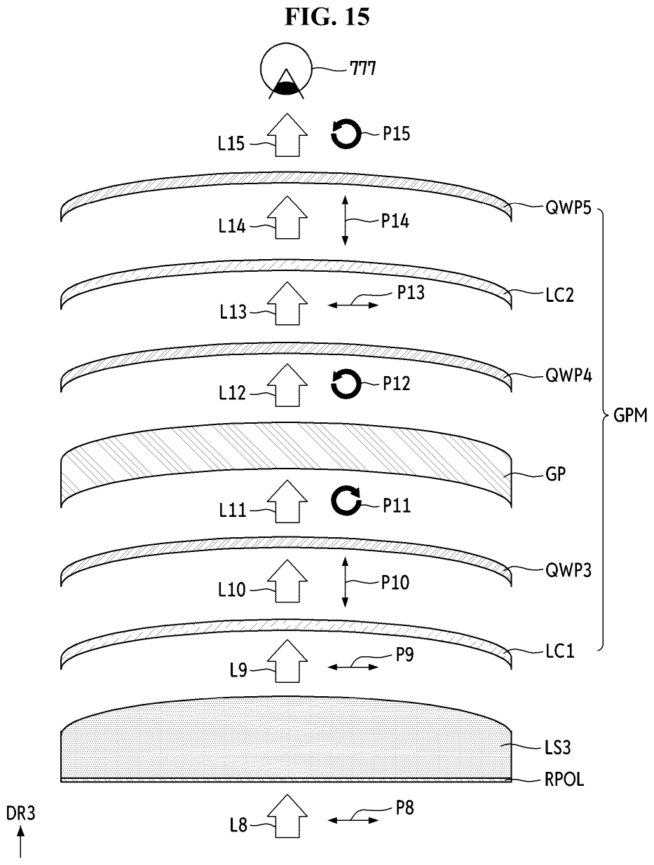

FIGS. 14 and 15 are views for describing a movement path of light in a display device of FIG. 12.

First light L1 from the display panel 100 may be light in a state P1 in which it is not polarized. For example, the first light L1 may be light emitted from the light emitting element. In one or more embodiments, the first light L1 emitted from the light emitting element may be provided to the absorptive polarization layer APOL through the color filter layer CFL.

The first light L1 from the display panel 100 may be incident on the absorptive polarization layer APOL. Light in a direction parallel to a transmission axis (or polarization axis) of the absorptive polarization layer APOL from among the first light L1 may pass through the absorptive polarization layer APOL. For example, second light L2 that has passed through the absorptive polarization layer APOL from among the first light L1 may have a state P2 in which it is linearly polarized in a direction of 30 45°. In other words, the second light L2 may be light linearly polarized in the direction of +45°.

The second light L2 may be incident on the first phase delay layer QWP1. The second light L2 may be converted into third light L3 while passing through the first phase delay layer QWP1. For example, the third light L3 may have a state P3 in which it is circularly polarized in a left direction (or the counterclockwise direction). In other words, the third light L3 may be light circularly polarized in the counterclockwise direction.

The third light L3 may be incident on the translucent mirror HM. Some of the third light L3 may be reflected by the translucent mirror HM and incident on the first phase delay layer QWP1, and the other ones of the third light L3 may pass through the translucent mirror HM. The third light L3 may sequentially pass through the translucent mirror HM and the first lens LS1. Fourth light L4 that has sequentially passed through the translucent mirror HM and the first lens LS1 may have the same polarization state P4 as the third light L3. For example, the fourth light L4 may have a state P4 in which it is circularly polarized in the left direction (or the counterclockwise direction). In other words, the fourth light L4 may be light circularly polarized in the counterclockwise direction.

The fourth light L4 may pass through the second lens LS2 and may be incident on the second phase delay layer QWP2. The fourth light L4 may be converted into fifth light L5 while passing through the second phase delay layer QWP2. For example, the fifth light L5 may have a state P5 in which it is linearly polarized in a direction of 90°. In other words, the fifth light L5 may be light linearly polarized in the direction of 90°.

The fifth light L5 may be incident on the reflective polarization layer RPOL. The fifth light L5 may be reflected by the reflective polarization layer RPOL. For example, a polarization direction of the fifth light L5 crosses a transmission axis of the reflective polarization layer RPOL, and thus, the fifth light L5 may be reflected by the reflective polarization layer RPOL.

The fifth light L5 reflected by the reflective polarization layer RPOL may be incident on the second phase delay layer QWP2. The fifth light L5 may be converted into sixth light L6 while passing through the second phase delay layer QWP2. For example, the sixth light L6 may have a state P6 in which it is circularly polarized in the left direction (or the counterclockwise direction). In other words, the sixth light L6 may be light circularly polarized in the counterclockwise direction. The sixth light L6 may pass through the second lens LS2.

The sixth light L6 that has passed through the second lens LS2 may be incident on the first lens LS1. The sixth light L6 that has passed through the first lens LS1 may be incident on the translucent mirror HM. The sixth light L6 may be reflected by the translucent mirror HM and converted into seventh light L7. For example, the seventh light L7 may have a state P7 in which it is circularly polarized in a right direction (or the clockwise direction). In other words, the seventh light L7 may be light circularly polarized in the clockwise direction. The seventh light L7 reflected by the translucent mirror HM may pass through the first lens LS1 and may be incident on the second lens LS2.

The seventh light L7 incident on the second lens LS2 may pass through the second lens LS2 and may be incident on the second phase delay layer QWP2. The seventh light L7 may be converted into eight light L8 while passing through the second phase delay layer QWP2. For example, the eighth light L8 may have a state P8 in which it is linearly polarized in a direction of 0°. In other words, the eighth light L8 may be light linearly polarized in the direction of 0°. An angle between a polarization direction of the eighth light L8 and the polarization direction of the fifth light L5 may be 90°. In other words, the polarization direction of the eighth light L8 and the polarization direction of the fifth light L5 may form an angle of 90°. Accordingly, the eighth light L8 may pass through the reflective polarization layer RPOL. For example, the polarization direction of the eighth light L8 is parallel to the transmission axis of the reflective polarization layer RPOL, and thus, the eighth light L8 may pass through the reflective polarization layer RPOL.

The eighth light L8 that has passed through the reflective polarization layer RPOL may be incident on the geometric phase module GPM through the third lens LS3. For example, as illustrated in FIG. 15, ninth light L9 that has sequentially passed through the reflective polarization layer RPOL and the third lens LS3 may have a state P9 in which it is linearly polarized in the direction of 0°, and may be incident on the first linear polarization conversion layer LC1 of the geometric phase module GPM.

The ninth light L9 may be converted into tenth light L10 while passing through the first linear polarization conversion layer LC1. For example, the tenth light L10 may have a state P10 in which it is linearly polarized in the direction of 0°. In other words, the tenth light L10 may be light linearly polarized in the direction of 0°. An angle between a polarization direction of the tenth light L10 and a polarization direction of the ninth light L9 may be 90°. In other words, the polarization direction of the tenth light L10 and the polarization direction of the ninth light L9 may form an angle of 90°.

The tenth light L10 may be incident on the third phase delay layer QWP3. The tenth light L10 may be converted into eleventh light L11 while passing through the third phase delay layer QWP3. For example, the eleventh light L11 may have a state P11 in which it is circularly polarized in the right direction (or the clockwise direction). In other words, the eleventh light L11 may be light circularly polarized in the clockwise direction.

The eleventh light L11 may be incident on the geometric phase lens GP. The eleventh light L11 may be converted into twelfth light L12 while passing through the geometric phase lens GP. For example, the twelfth light L12 may have a state P12 in which it is circularly polarized in the left direction (or the counterclockwise direction). In other words, the twelfth light L12 may be light circularly polarized in the counterclockwise direction.

The twelfth light L12 may be incident on the fourth phase delay layer QWP4. The twelfth light L12 may be converted into thirteenth light L13 while passing through the fourth phase delay layer QWP4. For example, the thirteenth light L13 may have a state P13 in which it is linearly polarized in the direction of 0°. In other words, the thirteenth light L13 may be light linearly polarized in the direction of 0°.

The thirteenth light L13 may be incident on the second linear polarization conversion layer LC2. The thirteenth light L13 may be converted into fourteenth light L14 while passing through the second linear polarization conversion layer LC2. For example, the fourteenth light L14 may have a state P14 in which it is linearly polarized in the direction of 90°. In other words, the fourteenth light L14 may be light linearly polarized in the direction of 90°. An angle between a polarization direction of the fourteenth light L14 and a polarization direction of the thirteenth light L13 may be 90°. In other words, the polarization direction of the fourteenth light L14 and the polarization direction of the thirteenth light L13 may form an angle of 90°.

The fourteenth light L14 may be incident on the fifth phase delay layer QWP5. The fourteenth light L14 may be converted into fifteenth light L15 while passing through the fifth phase delay layer QWP5. For example, the fifteenth light L15 may have a state P15 in which it is circularly polarized in the left direction (or the counterclockwise direction). In other words, the fifteenth light L15 may be light circularly polarized in the counterclockwise direction.

The fifteenth light L15 may be incident on a user's eye 777. For example, the fifteenth light L15 that has passed through the fifth phase delay layer QWP5 may have a state in which it is circularly polarized in the left direction (or the counterclockwise direction), and may be incident on the user's eye 777.

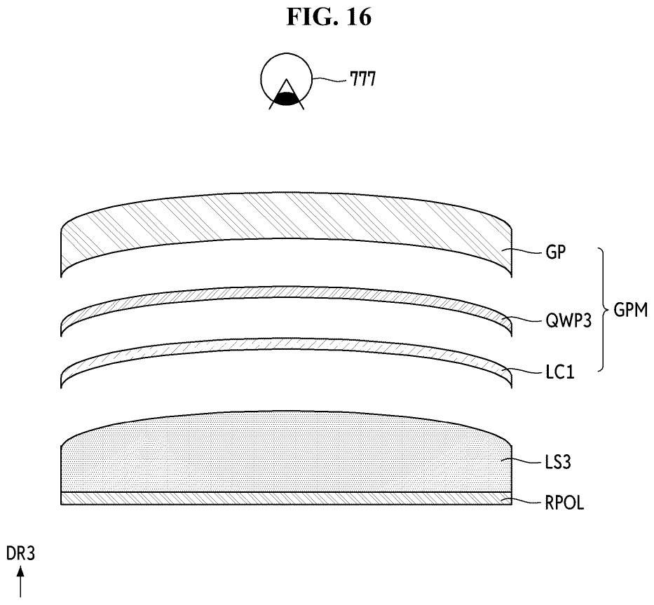

FIG. 16 is a detailed configuration diagram of another embodiment of the geometric phase module GPM of FIG. 12.

The geometric phase module GPM may include a first linear polarization conversion layer LC1, a third phase delay layer QWP3, and a geometric phase lens GP, as illustrated in FIG. 16. For example, the fourth phase delay layer QWP4, the second linear polarization conversion layer LC2, and the fifth phase delay layer QWP5 from among components of the geometric phase module GPM of FIG. 13 may be omitted. In this case, the twelfth light L12 in FIG. 15 may be incident on the user's eye 777.

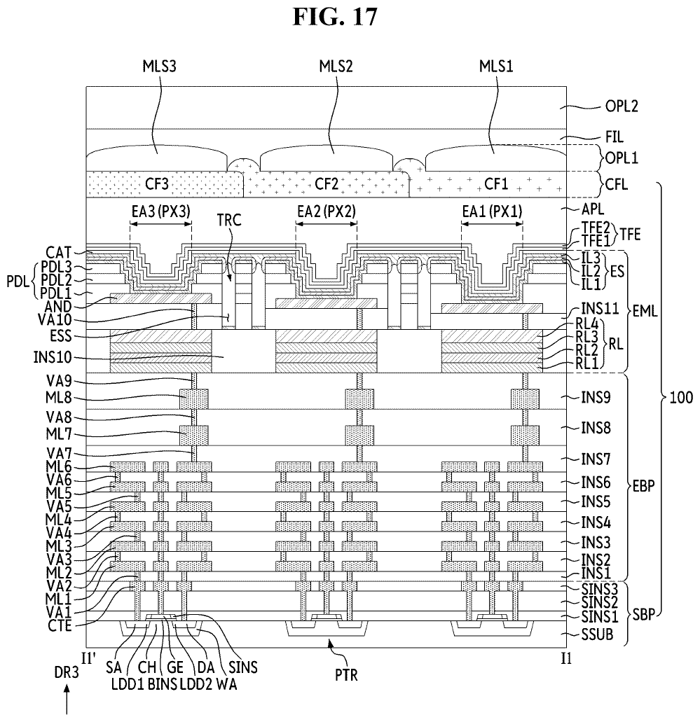

FIG. 17 is a cross-sectional view illustrating another embodiment of the display device taken along the line I1-I1′ of FIG. 5.

The display device of FIG. 17 is different from the display device described above with reference to FIG. 7 in that it includes two optical layers OPL, and such a difference will be mainly described below.

As illustrated in FIG. 17, the display device may further include a first optical layer OPL1 disposed between the color filter layer CFL and the filling layer FIL.

The first optical layer OPL1 may include a plurality of micro lenses. For example, the first optical layer OPL1 may include a first micro lens MLS1, a second micro lens MLS2, and a third micro lens MLS3.

The first micro lens MLS1 may be disposed on the first color filter CF1. For example, the first micro lens MLS1 may be disposed on the first color filter CF1 so as to overlap the first color filter CF1. In other words, the first micro lens MLS1 may be disposed between the first color filter CF1 and the filling layer FIL. In this case, the first micro lens MLS1 may be in contact with the first color filter CF1.

The second micro lens MLS2 may be disposed on the second color filter CF2. For example, the second micro lens MLS2 may be disposed on the second color filter CF2 so as to overlap the second color filter CF2. In other words, the second micro lens MLS2 may be disposed between the second color filter CF2 and the filling layer FIL. In this case, the second micro lens MLS2 may be in contact with the second color filter CF2.

The third micro lens MLS3 may be disposed on the third color filter CF3. For example, the third micro lens MLS3 may be disposed on the third color filter CF3 so as to overlap the third color filter CF3. In other words, the third micro lens MLS3 may be disposed between the third color filter CF3 and the filling layer FIL. In this case, the third micro lens MLS3 may be in contact with the third color filter CF3.

A second optical layer OPL2 may be disposed on the filling layer FIL. For example, the second optical layer OPL2 may be disposed on the filling layer FIL so as to overlap all of the first micro lens MLS1, the second micro lens MLS2, and the third micro lens MLS3. The second optical layer OPL2 may be the same as the optical layer OPL described above with reference to FIG. 7. In this case, the second optical layer OPL2 may have the same configuration as the optical layer OPL described above with reference to FIGS. 8 and 9. As another example embodiment, the second optical layer OPL2 may have the same configuration as the optical layer OPL described above with reference to FIGS. 12 and 13.

The above-described display panel 100 may have a curved shape like the geometric phase module GPM of FIG. 8 or the geometric phase module GPM of FIG. 12.

In addition, each of the above-described absorptive polarization layer APOL and reflective polarization layer RPOL may have a curved shape like the geometric phase module GPM of FIG. 8 or the geometric phase module GPM of FIG. 12.

According to one or more embodiments, the display device may include a plurality of geometric phase modules GPM. For example, the optical layer OPL of FIG. 8 may further include the geometric phase module GPM disposed on the third lens LS3 as illustrated in FIG. 12. In this case, a depth of a virtual image of the display device may be improved to 2ⁿ. Here, n is the number of geometric phase modules GPM, and may be a natural number. For example, when the optical layer OPL has two geometric phase modules GPM, the display device may express four (or four-level) depths.

According to one or more embodiments, when the optical layer OPL of the display device includes the plurality of geometric phase modules GPM, the plurality of geometric phase modules GPM may be disposed to be in direct contact with each other.

According to one or more embodiments, the geometric phase module GPM may be disposed at any position within the optical layer OPL. As an example, the geometric phase module GPM of FIG. 8 may be disposed between the translucent mirror HM and the first lens LS1. As another example, the geometric phase module GPM of FIG. 8 may be disposed between the first lens LS1 and the second lens LS2. As still another example, the geometric phase module GPM of FIG. 8 may be disposed between the second lens LS2 and the first phase delay layer QWP1.

According to one or more embodiments, the geometric phase module GPM may have various curved shapes with a single curvature or a double curvature. In addition, according to one or more embodiments, the geometric phase module GPM may have the shape of a free-form surface.

According to one or more embodiments, because the geometric phase module GPM has a cross section with a curved shape, for example, the light of the first color (e.g., the light of the blue wavelength band) from the first pixel PX1, the light of the second color (e.g., the light of the green wavelength band) from the second pixel PX2, and the light of the third color (e.g., the light of the red wavelength band) from the third pixel PX3 may overlap each other at one focus. Accordingly, chromatic aberration of the geometric phase module GPM may be reduced, such that image quality of the display device may be improved.

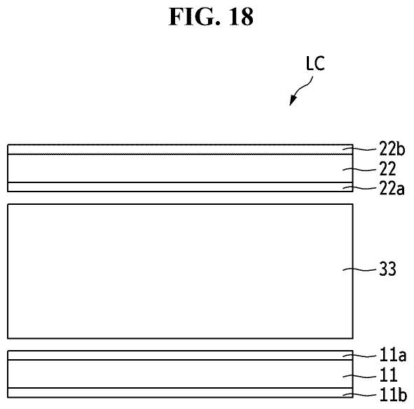

FIG. 18 is a cross-sectional view of a linear polarization conversion layer according to one or more embodiments. For example, the linear polarization conversion layer of FIG. 18 may be a cross-sectional view of the first linear polarization conversion layer LC1 of FIG. 9.

The linear polarization conversion layer LC may include a first polarization layer 11b, a first substrate 11, a first counter electrode 11a, a liquid crystal layer 33, a second counter electrode 22a, a second substrate 22, and a second polarization layer 22b.

The liquid crystal layer 33 may be disposed between the first substrate 11 and the second substrate 22. Here, surfaces of the first substrate 11 and the second substrate 22 facing each other are defined as an inner surface of the first substrate 11 and an inner surface of the second substrate 22, respectively. In addition, a surface of the first substrate 11 disposed on a side opposite to the inner surface of the first substrate 11 is defined as an outer surface of the first substrate 11, and a surface of the second substrate 22 disposed on a side opposite to the inner surface of the second substrate 22 is defined as an outer surface of the second substrate 22.

The liquid crystal layer 33 may include a twisted nematic liquid crystal.

The first counter electrode 11a may be disposed on the inner surface of the first substrate 11. A voltage may be applied to the first counter electrode 11a.

The first polarization layer 11b may be disposed on the outer surface of the first substrate 11. A transmission axis (or a polarization axis) of the first polarization layer 11b and a transmission axis (or a polarization axis) of the above-described absorptive polarization layer APOL may have the same direction. An angle between the first polarization layer 11b and the transmission axis of the above-described absorptive polarization layer APOL may be 90°.

The second counter electrode 22a may be disposed on the inner surface of the second substrate 22. A voltage may be applied to the second counter electrode 22a.

The second polarization layer 22b may be disposed on the outer surface of the second substrate 22. A transmission axis (or a polarization axis) of the second polarization layer 22b and the transmission axis (or the polarization axis) of the first polarization layer 11b may form an angle of 90°.

In one or more embodiments, a voltage may not be applied to the first counter electrode 11a and the second counter electrode 22a. In such a case, an electric field is not applied to the liquid crystal layer 33, and thus, liquid crystal molecules of the liquid crystal layer 33 may be maintained in a twisted state. Accordingly, light incident on the linear polarization conversion layer LC through the first polarization layer 11b may be emitted in a polarization state in which it is twisted by 90° through the second polarization layer 22b.

When the linear polarization conversion layer LC described above with reference to FIG. 18 is used as the first linear polarization conversion layer LC1 described above with reference to FIG. 9, the first polarization layer 11b of the linear polarization conversion layer LC may face the absorptive polarization layer APOL, and the second polarization layer 22b of the linear polarization conversion layer LC may face the second phase delay layer QWP2.

When the linear polarization conversion layer LC described above with reference to FIG. 18 is used as the second linear polarization conversion layer LC2 described above with reference to FIG. 9, the first polarization layer 11b of the linear polarization conversion layer LC may face the third phase delay layer QWP3, and the second polarization layer 22b of the linear polarization conversion layer LC may face the fourth phase delay layer QWP4.

In addition, when the linear polarization conversion layer LC described above with reference to FIG. 18 is used as the first linear polarization conversion layer LC1 described above with reference to FIG. 13, the first polarization layer 11b of the linear polarization conversion layer LC may face the third lens LS3, and the second polarization layer 22b of the linear polarization conversion layer LC may face the third phase delay layer QWP3.

When the linear polarization conversion layer LC described above with reference to FIG. 18 is used as the second linear polarization conversion layer LC2 described above with reference to FIG. 13, the first polarization layer 11b of the linear polarization conversion layer LC may face the fourth phase delay layer QWP4, and the second polarization layer 22b of the linear polarization conversion layer LC may face the fifth phase delay layer QWP5.

Each of the first polarization layer 11b, the first substrate 11, the first counter electrode 11a, the liquid crystal layer 33, the second counter electrode 22a, the second substrate 22, and the second polarization layer 22b of the linear polarization conversion layer LC described above may have a curved shape like the first linear polarization conversion layer LC1 of FIG. 9.

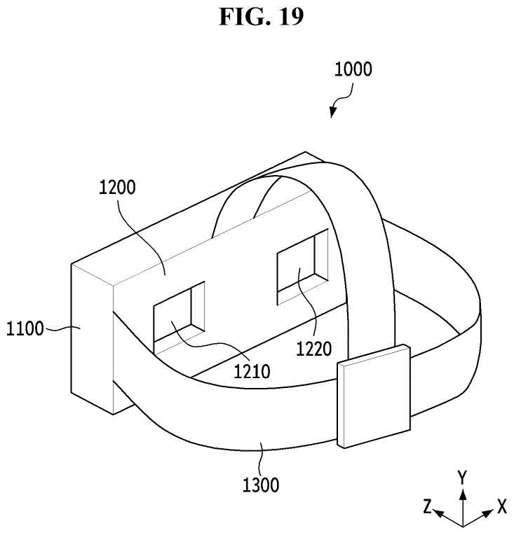

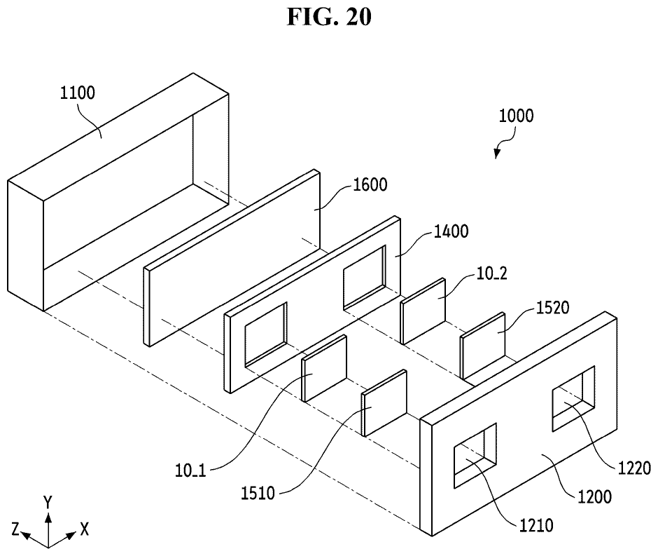

FIG. 19 is a perspective view illustrating a head mounted display device according to one or more embodiments. FIG. 20 is an exploded perspective view illustrating an example of the head mounted display device of FIG. 19.

Referring to FIGS. 19 and 20, a head mounted display device 1000 according to one or more embodiments includes a first display device 10_1, a second display device 10_2, a display device housing portion 1100, a housing portion cover 1200, a first eyepiece 1210, a second eyepiece 1220, a head mounted band 1300, a middle frame 1400, a first optical member 1510, a second optical member 1520, and a control circuit board 1600.

The first display device 10_1 provides an image to a user's left eye, and the second display device 10_2 provides an image to a user's right eye. Each of the first display device 10_1 and the second display device 10_2 is substantially the same as the display device 10 described with reference to FIGS. 1 to 17, and a description of the first display device 10_1 and the second display device 10_2 is thus omitted.

The first optical member 1510 may be disposed between the first display device 10_1 and the first eyepiece 1210. The second optical member 1520 may be disposed between the second display device 10_2 and the second eyepiece 1220. Each of the first optical member 1510 and the second optical member 1520 may include at least one convex lens.

The middle frame 1400 may be disposed between the first display device 10_1 and the control circuit board 1600 and disposed between the second display device 10_2 and the control circuit board 1600. The middle frame 1400 serves to support and fix the first display device 10_1, the second display device 10_2, and the control circuit board 1600.

The control circuit board 1600 may be disposed between the middle frame 1400 and the display device housing portion 1100. The control circuit board 1600 may be connected to the first display device 10_1 and the second display device 10_2 through a connector. The control circuit board 1600 may convert an image source input from the outside into digital video data DATA, and transmit the digital video data DATA to the first display device 10_1 and the second display device 10_2 through the connector.

The control circuit board 1600 may transmit digital video data DATA corresponding to a left eye image optimized for the user's left eye to the first display device 10_1 and transmit digital video data DATA corresponding to a right eye image optimized for the user's right eye to the second display device 10_2. Alternatively, the control circuit board 1600 may transmit the same digital video data DATA to the first display device 10_1 and the second display device 10_2.

The display device housing portion 1100 serves to house the first display device 10_1, the second display device 10_2, the middle frame 1400, the first optical member 1510, the second optical member 1520, and the control circuit board 1600. The housing portion cover 1200 is disposed to cover opened one surface of the display device housing portion 1100. The housing portion cover 1200 may include the first eyepiece 1210 on which the user's left eye is disposed and the second eyepiece 1220 on which the user's right eye is disposed. It has been illustrated in FIGS. 19 and 20 that the first eyepiece 1210 and the second eyepiece 1220 are separately disposed, but the present disclosure is not limited thereto. The first eyepiece 1210 and the second eyepiece 1220 may be merged as one eyepiece.

The first eyepiece 1210 may be aligned with the first display device 10_1 and the first optical member 1510, and the second eyepiece 1220 may be aligned with the second display device 10_2 and the second optical member 1520. Accordingly, a user may view an image of the first display device 10_1 magnified as a virtual image by the first optical member 1510 through the first eyepiece 1210, and may view an image of the second display device 10_2 magnified as a virtual image by the second optical member 1520 through the second eyepiece 1220.

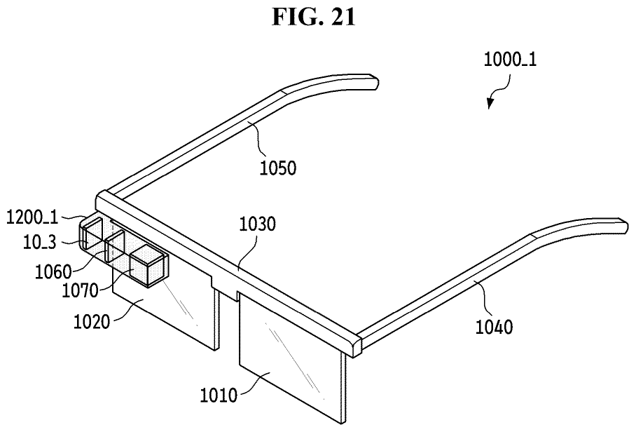

The head mounted band 1300 serves to fix the display device housing portion 1100 to a user's head so that the first eyepiece 1210 and the second eyepiece 1220 of the housing portion cover 1200 may be maintained in a state where they are disposed on the user's left eye and right eye, respectively. When the display device housing portion 1200 is implemented to have a light weight and a small size, the head mounted display device 1000 may include an eyeglass frame as illustrated in FIG. 21 instead of the head mounted band 800.

In addition, the head mounted display device 1000 may further include a battery for supplying power, an external memory slot for housing an external memory, and an external connection port and a wireless communication module for receiving an image source. The external connection port may be a universe serial bus (USB) terminal, a display port, or a high-definition multimedia interface (HDMI) terminal, and the wireless communication module may be a 5G communication module, a 4G communication module, a wireless fidelity (WiFi) module, or a Bluetooth module.

FIG. 21 is a perspective view illustrating a head mounted display according to another example embodiment.

Referring to FIG. 21, a head mounted display device 1000_1 according to another example embodiment may be a glasses-type display device in which a display device housing portion 1200_1 is implemented to have a light weight and a small size. The head mounted display device 1000_1 according to another example embodiment may include a display device 10_3, a left eye lens 1010, a right eye lens 1020, a support frame 1030, glasses frame legs 1040 and 1050, an optical member 1600, an optical path conversion member 1070, and a display device housing portion 1200_1.

The display device housing portion 1200_1 may include the display device 10_3, the optical member 1600, and the optical path conversion member 1070. An image displayed on the display device 10_3 may be magnified by the optical member 1600, converted in an optical path by the optical path conversion member 1070, and provided to a user's right eye through the right eye lens 1020. For this reason, a user may view an augmented reality image in which a virtual image displayed on the display device 10_3 through his/her right eye and a real image seen through the right eye lens 1020 are combined with each other.

It has been illustrated in FIG. 21 that the display device housing portion 1200_1 is disposed at a right end of the support frame 1030, but the present disclosure is not limited thereto. For example, the display device housing portion 1200_1 may be disposed at a left end of the support frame 1030, and in this case, an image of the display device 10_3 may be provided to a user's left eye. Alternatively, the display device housing portions 1200_1 may be disposed at both the left and right ends of the support frame 1030, and in this case, the user may view an image displayed on the display device 10_3 through both his/her left and right eyes.

It will be able to be understood by one of ordinary skill in the art to which the present disclosure belongs that the present disclosure may be implemented in other specific forms without changing the technical spirit or essential features of the present disclosure. Therefore, it is to be understood that the embodiments described above are illustrative rather than being restrictive in all aspects. It is to be understood that the scope of the present disclosure are defined by the claims rather than the detailed description described above and all modifications and alterations derived from the claims and their equivalents fall within the scope of the present disclosure.

What is claimed is:

1. A display device comprising:
a display panel; and
a first optical layer on the display panel,
wherein the first optical layer comprises a geometric phase module having a cross section with a curved shape.

2. The display device of claim 1, wherein the first optical layer further comprises a lens between the display panel and the geometric phase module.

3. The display device of claim 2, wherein the geometric phase module comprises a geometric phase lens, and
wherein a curvature of the geometric phase lens and a curvature of the lens are same as each other.

4. The display device of claim 1, wherein the first optical layer further comprises:
an absorptive polarization layer on the display panel;
a translucent mirror on the absorptive polarization layer;
a first lens on the translucent mirror;
a second lens on the first lens;
a phase delay layer on the second lens;
a reflective polarization layer on the phase delay layer; and
a third lens on the reflective polarization layer.

5. The display device of claim 4, wherein the geometric phase module is between the absorptive polarization layer and the translucent mirror.

6. The display device of claim 1, wherein the first optical layer further comprises:
an absorptive polarization layer on the display panel;
a first phase delay layer on the absorptive polarization layer;
a translucent mirror on the first phase delay layer;
a first lens on the translucent mirror;
a second lens on the first lens;
a second phase delay layer on the second lens;
a reflective polarization layer on the second phase delay layer; and
a third lens on the reflective polarization layer.

7. The display device of claim 6, wherein the geometric phase module is on the third lens.

8. The display device of claim 1, wherein the geometric phase module comprises:
a first linear polarization conversion layer;
a first phase delay layer on the first linear polarization conversion layer; and
a geometric phase lens on the first phase delay layer, and
wherein the geometric phase lens has a cross section with a curved shape.

9. The display device of claim 8, wherein the geometric phase module further comprises:
a second phase delay layer on the geometric phase lens;
a second linear polarization conversion layer on the second phase delay layer; and
a third phase delay layer on the second linear polarization conversion layer.

10. The display device of claim 1, further comprising a second optical layer between the display panel and the first optical layer.

11. The display device of claim 10, wherein the second optical layer comprises a plurality of micro lenses.

12. The display device of claim 11, wherein the plurality of micro lenses corresponds to a plurality of color filters of the display panel.

13. The display device of claim 10, further comprising a filling layer between the first optical layer and the second optical layer.

14. An optical device comprising:
a display device; and
an optical path conversion member on the display device,
wherein the display device comprises:
a display panel; and
a first optical layer on the display panel,
wherein the first optical layer comprises a geometric phase module having a cross section with a curved shape.

15. The optical device of claim 14, wherein the first optical layer further comprises a lens between the display panel and the geometric phase module.

16. The optical device of claim 15, wherein the geometric phase module comprises a geometric phase lens, and
wherein a curvature of the geometric phase lens and a curvature of the lens are same as each other.

17. The optical device of claim 14, wherein the first optical layer further comprises:
an absorptive polarization layer on the display panel;
a translucent mirror on the absorptive polarization layer;
a first lens on the translucent mirror;
a second lens on the first lens;
a phase delay layer on the second lens;
a reflective polarization layer on the phase delay layer; and
a third lens on the reflective polarization layer,
wherein the geometric phase module is between the absorptive polarization layer and the translucent mirror.

18. The optical device of claim 14, wherein the first optical layer further comprises:
an absorptive polarization layer on the display panel;
a first phase delay layer on the absorptive polarization layer;
a translucent mirror on the first phase delay layer;
a first lens on the translucent mirror;
a second lens on the first lens;
a second phase delay layer on the second lens;
a reflective polarization layer on the second phase delay layer; and
a third lens on the reflective polarization layer,
wherein the geometric phase module is on the third lens.

19. An electronic device comprising a display device, the display device comprises:
a display panel;
a first optical layer on the display panel; and
a second optical layer between the display panel and the first optical layer,
wherein the first optical layer comprises a geometric phase module having a cross section with a curved shape.

20. The electronic device of claim 19, wherein the electronic device comprises a mobile phone, a smartphone, a tablet personal computer, a mobile communication terminal, an electronic book, a portable multimedia player (PMP), a navigation system, an ultra mobile PC (UMPC), a television, a laptop, a monitor, a billboard, or an Internet-of-Things (IoT) terminal.
